(19) United States
(12) Patent Application Publication
(10) Pub. No.: US 2024/0345480 A1
(43) Pub. Date: Oct. 17, 2024

(54) MOLECULAR RESIST COMPOSITION AND PATTERNING PROCESS

(71) Applicant: Shin-Etsu Chemical Co., Ltd., Tokyo (JP)

(72) Inventors: Masaki Ohashi, Joetsu-shi (JP); Shun Kikuchi, Joetsu-shi (JP); Seiichiro Tachibana, Joetsu-shi (JP); Ryunosuke Handa, Joetsu-shi (JP)

(73) Assignee: Shin-Etsu Chemical Co., Ltd., Tokyo (JP)

(21) Appl. No.: 18/625,950

(22) Filed: Apr. 3, 2024

(30) Foreign Application Priority Data
Apr. 13, 2023 (JP) 2023-065363

(51) Int. Cl. G03F 7/029; G03F 7/32

(52) U.S. Cl. CPC G03F 7/029; G03F 7/325

(57) ABSTRACT

The negative-tone molecular resist composition comprises an onium salt containing a cation having a cyclic ether site and an organic solvent has a high sensitivity and forms a resist film with improved resolution and LWR when processed by photolithography using high-energy radiation. The molecular resist composition of the invention meets both high sensitivity and high resolution and is improved in LWR when processed by photolithography using high-energy radiation, especially EB or EUV lithography. The resist composition is quite useful for precise micropatterning.

### CROSS-REFERENCE TO RELATED APPLICATIONS

This non-provisional application claims priority under 35 U.S.C. § 119 (a) on Patent Application No. 2023-065363 filed in Japan on Apr. 13, 2023, the entire contents of which are hereby incorporated by reference.

### TECHNICAL FIELD

This invention relates to a molecular resist composition and a pattern forming process.

### BACKGROUND ART

While a higher integration density, higher operating speed and lower power consumption of LSIs are demanded to comply with the expanding IoT market, the effort to reduce the pattern rule is in rapid progress. The wide-spreading logic device market drives forward the miniaturization technology. As the advanced miniaturization technology, microelectronic devices of 10-nm node are manufactured in a mass scale by the double, triple or quadro-patterning version of the ArF immersion lithography. The manufacture of 7-nm node devices by the next generation EUV lithography of wavelength 13.5 nm is investigated.

In the EUV lithography, chemically amplified resist compositions are applicable to form line patterns to a line width of 20 nm or less. When a polymeric resist composition commonly used in the ArF lithography is used in the EUV lithography, such problems as roughening of pattern surface and difficulty of pattern control arise because the base polymer in the composition has a large molecular size. To overcome the problems, a variety of low-molecular-weight materials are proposed.

Molecular resist compositions are based on low-molecular-weight compounds and free of base polymers commonly used in polymeric resist compositions. The molecular resist composition is expected as one of effective measures for forming small-size patterns. For example, Patent Document 1 discloses a negative tone radiation-sensitive composition adapted for alkaline development, comprising mainly a polyhydric polyphenol compound. Non-Patent Document 1 describes a positive tone resist composition adapted for alkaline development, comprising only an acid generator in the form of a sulfonium salt in which a cation having a tert-butoxycarbonyloxy group attached thereto is combined with a strong acid anion. Since the acid generator has a smaller molecular size than polymers, an improvement in roughness is expectable. However, since the molecular resist composition relying on the chemical amplification mechanism is difficult to control acid diffusion, no satisfactory performance has yet been established. In addition, the EUV resist composition must not only clear roughness, but also provide high sensitivity and resolution at the same time, with further improvements being desired.

One of the causes that retard the development of EUV lithography materials is a small number of photons available with EUV exposure. The energy of EUV is extremely higher than that of ArF excimer laser. The number of photons available with EUV exposure is 1/14 of the number by ArF exposure. The size of pattern features formed by the EUV lithography is less than half the size by the ArF lithography. Therefore, the EUV lithography is quite sensitive to a variation of photon number. A variation in number of photons in the radiation region of extremely short wavelength is shot noise as a physical phenomenon. It is impossible to eliminate the influence of shot noise. Attention is thus paid to stochastics. While it is impossible to eliminate the influence of shot noise, discussions are held how to reduce the influence. There is observed a phenomenon that under the influence of shot noise, values of CDU and LWR are increased and holes are blocked at a probability of one several millionth. The blockage of holes leads to electric conduction failure to prevent transistors from operation, adversely affecting the performance of an overall device.

As the means for reducing the influence of shot noise on the resist side, Patent Document 2 discloses an inorganic resist composition comprising a complex of an element having high EUV absorption. Although the inorganic resist composition has a relatively high sensitivity, it is not yet satisfactory because of outstanding problems including poor solubility in resist solvents, low shelf stability, and defectiveness.

### CITATION LIST

Patent Document 1: JP-A 2005-326838 (U.S. Pat. No. 7,871,751)
Patent Document 2: JP-A 2015-108781 (U.S. Pat. No. 9,366,960)
Non-Patent Document 1: Proc. of SPIE Vol. 6923, 69230K (2008)

### SUMMARY OF THE INVENTION

An object of the invention is to provide a molecular resist composition which is improved in sensitivity, resolution, and LWR when processed by photolithography using high-energy radiation, especially EB or EUV lithography; and a pattern forming process using the resist composition.

The inventors have found that a molecular resist composition comprising an onium salt containing a cation having a cyclic ether site has a high sensitivity and forms a resist film with improved resolution and LWR, so that the resist composition is quite useful for precise micropatterning.

In one aspect, the invention provides a negative-tone molecular resist composition comprising an onium salt containing a cation having a cyclic ether site and an organic solvent, the composition being free of a base polymer.

In a preferred embodiment, the onium salt is a sulfonium salt having the formula (1).

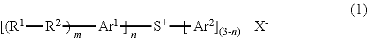

Herein m is an integer of 1 to 3, n is an integer of 1 to 3,
R¹ is a substituent group having a cyclic ether site, a plurality of R¹ may be the same or different when at least one of m and n is 2 or 3,
R² is a single bond, ether bond, ester bond, —N(H)—, thioether bond, sulfonate ester bond, sulfonamide bond, carbonate bond or carbamate bond,
Ar¹ is a C₆-C₂₀ (m+1)-valent aromatic hydrocarbon group in which some or all of the hydrogen atoms on the aromatic ring may be substituted by halogen or a C₁-C₂₀ hydrocarbyl moiety which may contain a heteroatom, a plurality of Ar¹ may be the same or different when n is 2 or 3,
Ar² is a C₆-C₂₀ aryl group in which some or all of the hydrogen atoms on the aromatic ring may be substituted by halogen or a C₁-C₂₀ hydrocarbyl moiety which may contain a heteroatom, two Ar² may be the same or different when n is 1,
two Ar¹, two Ar², or Ar¹ and Ar² may bond together to form a ring with the sulfur atom to which they are attached, and
X⁻ is a counter anion.

In a preferred embodiment, the cyclic ether site is an oxirane or oxetane ring.

In a preferred embodiment, X⁻ is a halide ion, nitrate ion, hydrogensulfate ion, hydrogencarbonate ion, borate ion, hexafluorophosphate ion, hexafluoroantimonate ion or an anion having any one of the formulae (X-1) to (X-7).

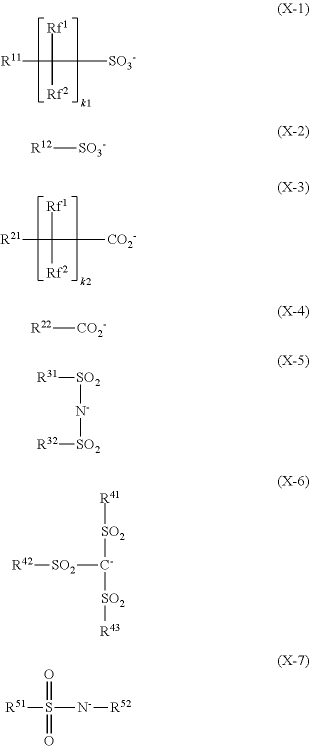

Herein k1 and k2 are each independently an integer of 1 to 4,
Rf¹ and Rf² are each independently hydrogen, fluorine or a C₁-C₆ fluorinated alkyl group, excluding that all Rf¹ and Rf² are hydrogen at the same time,
R¹¹ is hydrogen, halogen, hydroxy, or a C₁-C₄₀ hydrocarbyl group which may contain a heteroatom,
R¹² is hydrogen, halogen, hydroxy, or a C₁-C₄₀ hydrocarbyl group which may contain a heteroatom, exclusive of a hydrocarbyl group in which hydrogen on β- or β-carbon relative to the sulfo group is substituted by fluorine or fluoroalkyl,
R²¹ is hydrogen, halogen, hydroxy, or a C₁-C₄₀ hydrocarbyl group which may contain a heteroatom,
R²² is hydrogen, halogen, hydroxy, or a C₁-C₄₀ hydrocarbyl group which may contain a heteroatom, exclusive of a hydrocarbyl group in which hydrogen on β- or β-carbon relative to the carboxy group is substituted by fluorine or fluoroalkyl,
R³¹ and R³² are each independently a C₁-C₄₀ hydrocarbyl group which may contain a heteroatom,
R⁴¹ to R⁴³ are each independently a C₁-C₄₀ hydrocarbyl group which may contain a heteroatom,
R⁵¹ is fluorine or a C₁-C₁₀ fluorinated hydrocarbyl group which may contain hydroxy, ether bond or ester bond, R⁵² is hydrogen or a C₁-C₂₀ hydrocarbyl group which may contain hydroxy, ether bond or ester bond, R⁵¹ and R⁵² may bond together to form a ring with the atoms to which they are attached.

The molecular resist composition may further comprise an amine compound.

Preferably, at least two onium salts containing a cation having a cyclic ether site are present in the composition.

The molecular resist composition may further comprise an onium salt other than the onium salt containing a cation having a cyclic ether site.

The molecular resist composition may further comprise a surfactant.

In another aspect, the invention provides a pattern forming process comprising the steps of applying the negative-tone molecular resist composition defined herein onto a substrate to form a resist film thereon, exposing the resist film to high-energy radiation, and developing the exposed resist film in a developer.

In a preferred embodiment, the developing step uses an alkaline aqueous solution as the developer to form a negative tone pattern wherein the resist film in the unexposed region is dissolved away and the resist film in the exposed region is not dissolved.

In another preferred embodiment, the developing step uses an organic solvent as the developer to form a negative tone pattern wherein the resist film in the unexposed region is dissolved away and the resist film in the exposed region is not dissolved.

The organic solvent is preferably at least one solvent selected from among 2-octanone, 2-nonanone, 2-heptanone, 3-heptanone, 4-heptanone, 2-hexanone, 3-hexanone, diisobutyl ketone, methylcyclohexanone, acetophenone, methylacetophenone, propyl acetate, butyl acetate, isobutyl acetate, pentyl acetate, butenyl acetate, isopentyl acetate, propyl formate, butyl formate, isobutyl formate, pentyl formate, isopentyl formate, methyl valerate, methyl pentenoate, methyl crotonate, ethyl crotonate, methyl propionate, ethyl propionate, ethyl 3-ethoxypropionate, methyl lactate, ethyl lactate, propyl lactate, butyl lactate, isobutyl lactate, pentyl lactate, isopentyl lactate, methyl 2-hydroxyisobutyrate, ethyl 2-hydroxyisobutyrate, methyl benzoate, ethyl benzoate, phenyl acetate, benzyl acetate, methyl phenylacetate, benzyl formate, phenylethyl formate, methyl 3-phenylpropionate, benzyl propionate, and 2-phenylethyl acetate.

Typically, the high-energy radiation is EB or EUV.

### Advantageous Effects of Invention

The molecular resist composition of the invention meets both high sensitivity and high resolution and is improved in LWR when processed by photolithography using high-energy radiation, especially EB or EUV lithography. The resist composition is quite useful for precise micropatterning.

### BRIEF DESCRIPTION OF THE DRAWINGS

FIG. 1 is a diagram showing the 1H-NMR spectrum of sulfonium salt MR-1 in Synthesis Example 1.

FIG. 2 is a diagram showing the 1H-NMR spectrum of sulfonium salt MR-2 in Synthesis Example 2.

### DETAILED DESCRIPTION OF THE INVENTION

As used herein, the singular forms “a,” “an” and “the” include plural referents unless the context clearly dictates otherwise. The notation (Cn-Cm) means a group containing from n to m carbon atoms per group. In chemical formulae, the broken line designates a valence bond or point of attachment. The terms “group” and “moiety” are interchangeable. Me stands for methyl and Ac stands for acetyl.

The abbreviations and acronyms have the following meaning.
EB: electron beam
EUV: extreme ultraviolet
PEB: post-exposure bake
LWR: line width roughness
CDU: critical dimension uniformity

### [Molecular Resist Composition]

The invention provides a molecular resist composition comprising an onium salt containing a cation having a cyclic ether site (also referred to as “cyclic ether site-containing onium salt,” hereinafter) as a main component. As used herein, the main component means that the amount of this component is the most in the composition except an organic solvent.

### [Onium Salt]

Since the cation of the onium salt must be decomposed upon exposure to high-energy radiation, the cyclic ether site-containing onium salt is typically selected from a sulfonium salt, iodonium salt, selenonium salt, and bismuthonium salt. Of these, the sulfonium salt is preferred from the aspects of ease of synthesis and hydrophobicity of decomposed compounds.

The cyclic ether site-containing onium salt is preferably a sulfonium salt having the formula (1).

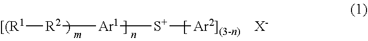

In formula (1), m is an integer of 1 to 3, and n is an integer of 1 to 3, preferably 2 or 3.

In formula (1), R¹ is a substituent group having a cyclic ether site. A plurality of R¹ may be the same or different when at least one of m and n is 2 or 3.

Suitable structures of the cyclic ether site include oxirane, oxetane, tetrahydrofuran, and tetrahydropyran rings, and fused rings of the following formulae.

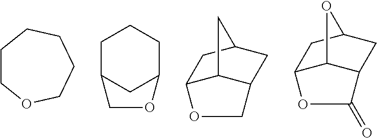

Most preferably the cyclic ether site is an oxirane or oxetane ring.

The substituent group having a cyclic ether site is preferably a C₂-C₂₀ group having a cyclic ether site. Suitable examples include C₂-C₂₀ saturated hydrocarbyl groups having a cyclic ether site and those groups in which some —CH₂— is replaced by an ether bond, ester bond, —N(H)—, thioether bond, sulfonate ester bond, sulfonamide bond, carbonate bond or carbamate bond.

In formula (1), R² is a single bond, ether bond, ester bond, —N(H)—, thioether bond, sulfonate ester bond, sulfonamide bond, carbonate bond or carbamate bond. Inter alia, a single bond, ether bond, ester bond, —N(H)—, sulfonate bond, and sulfonamide bond are preferred.

Examples of the group (R¹—R²)— are shown below, but not limited thereto. Herein, the broken line designates a point of attachment to Ar¹.

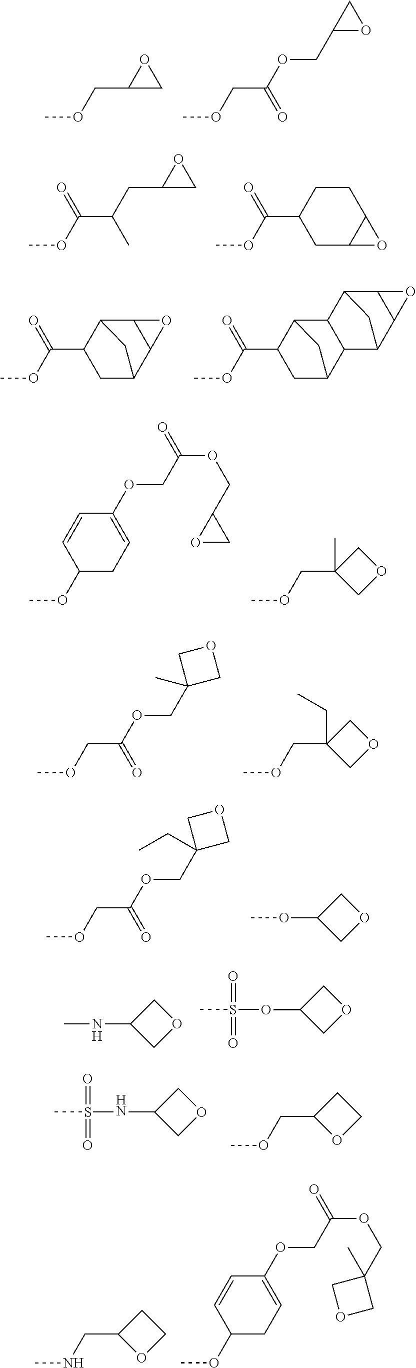

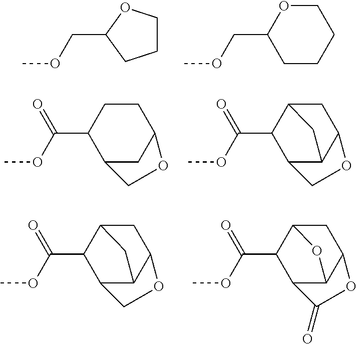

In formula (1), Ar¹ is a C₆-C₂₀ (m+1)-valent aromatic hydrocarbon group. Examples of the aromatic hydrocarbon group include arylene groups such as phenylene, naphthylene and anthracenediyl as well as groups obtained by removing one or two hydrogen atoms from the foregoing arylene groups. A plurality of Ar¹ may be the same or different when n is 2 or 3.

In formula (1), Ar² is a C₆-C₂₀ aryl group. Exemplary of the aryl group are phenyl, naphthyl and anthracenyl. Two Ar² may be the same or different when n is 1.

In the (m+1)-valent aromatic hydrocarbon group and aryl group, some or all of the hydrogen atoms on the aromatic ring may be substituted by halogen or a C₁-C₂₀ hydrocarbyl group which may contain a heteroatom. The C₁-C₂₀ hydrocarbyl group may be saturated or unsaturated and straight, branched or cyclic. Examples thereof include C₁-C₂₀ alkyl groups such as methyl, ethyl, propyl, isopropyl, n-butyl, sec-butyl, tert-butyl, tert-pentyl, n-pentyl, n-hexyl, n-octyl, 2-ethylhexyl, n-nonyl and n-decyl; C₃-C₂₀ cyclic saturated hydrocarbyl groups such as cyclopentyl, cyclohexyl, cyclopentylmethyl, cyclopentylethyl, cyclopentylbutyl, cyclohexylmethyl, cyclohexylethyl, cyclohexylbutyl, norbornyl, tricyclo [5.2.1.0^{2,6}] decyl, adamantyl, and adamantylmethyl; C₆-C₂₀ aryl groups such as phenyl, naphthyl and anthracenyl, and combinations thereof. In the hydrocarbyl group, some or all of the hydrogen atoms may be substituted by a moiety containing a heteroatom such as oxygen, sulfur, nitrogen or halogen, and some constituent —CH₂— may be replaced by a moiety containing a heteroatom such as oxygen, sulfur or nitrogen, so that the group may contain a hydroxy, cyano, halogen, carbonyl, ether bond, thioether bond, ester bond, sulfonate ester bond, carbonate bond, carbamate bond, lactone ring, sultone ring or carboxylic anhydride (—C(═O)—O—C(═O)—).

Two Ar¹, two Ar², or a pair of Ar¹ and Ar² may bond together to form a ring with the sulfur atom to which they are attached. Suitable ring structures are shown below, but not limited thereto.

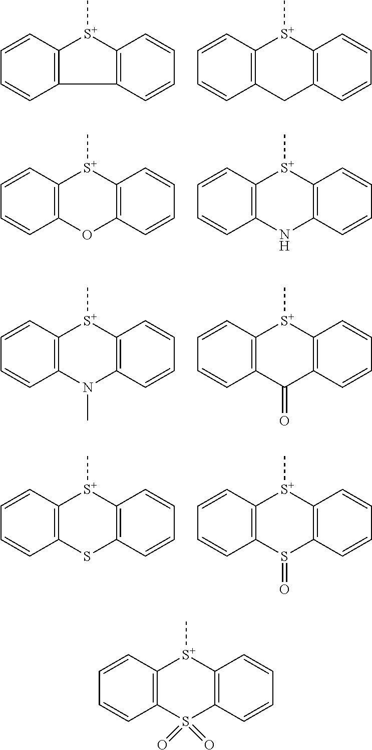

Examples of the cation in the sulfonium salt having formula (1) are shown below, but not limited thereto.

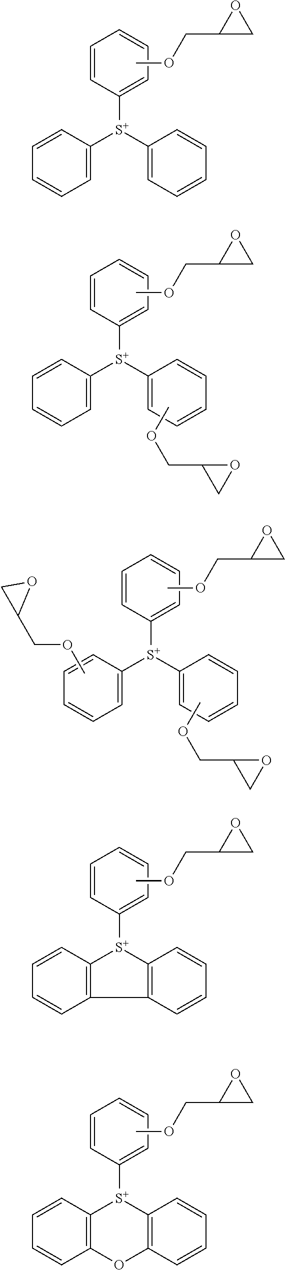

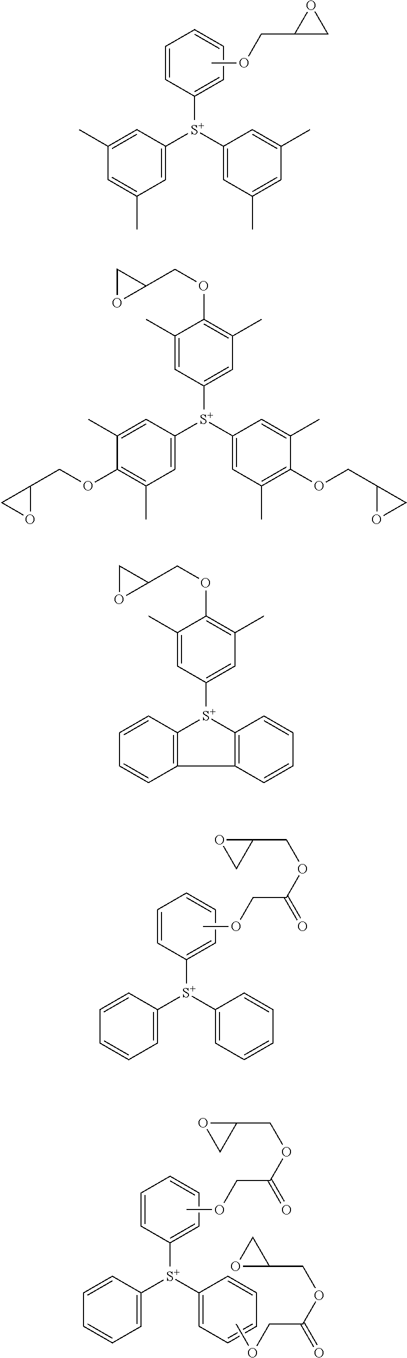

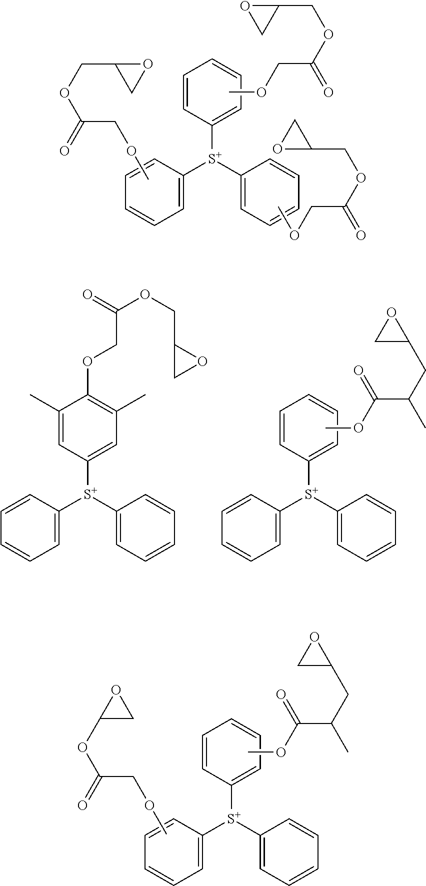

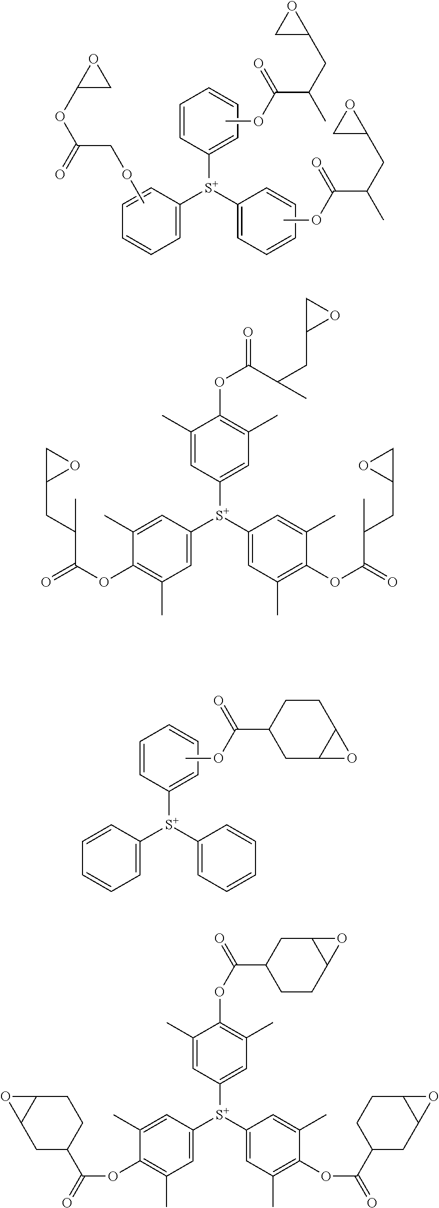

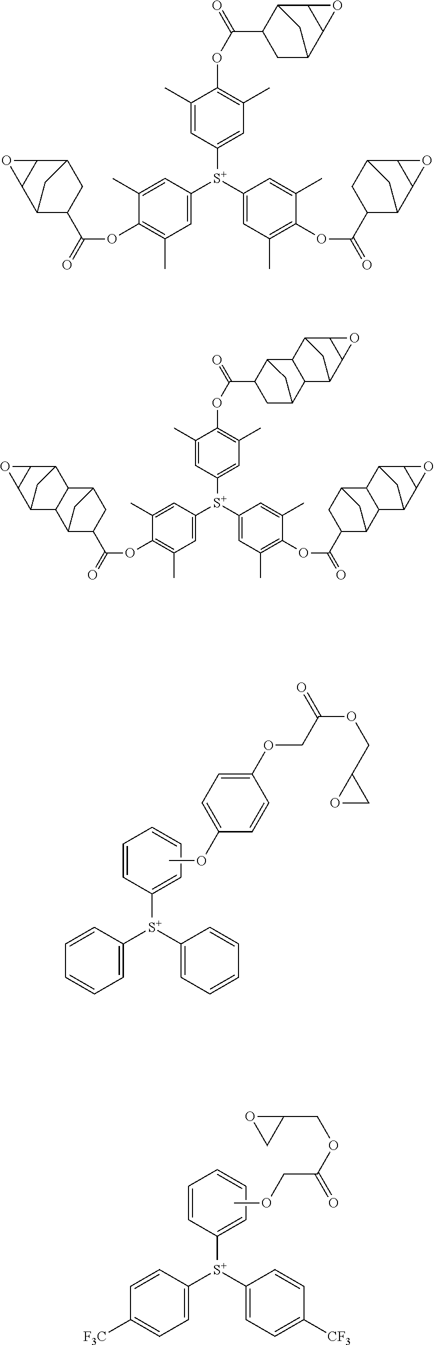

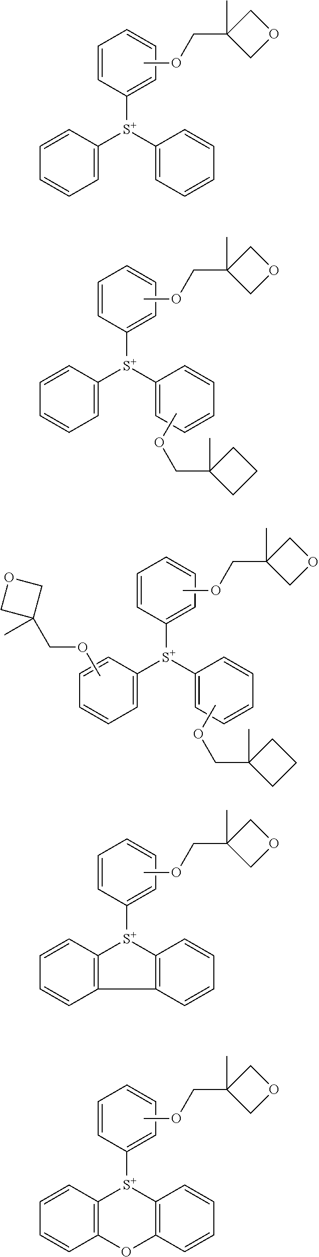

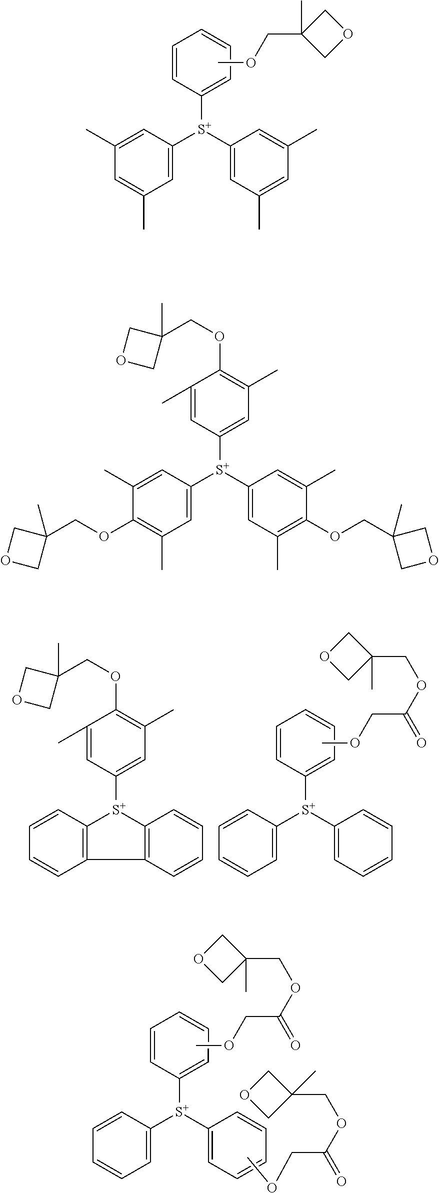

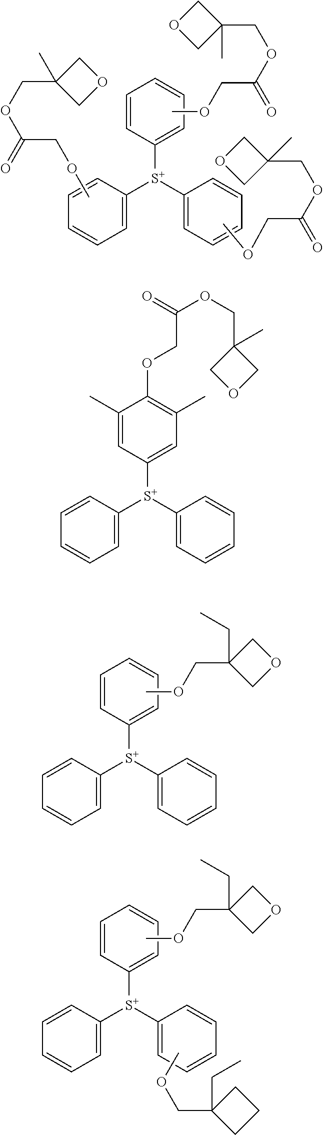

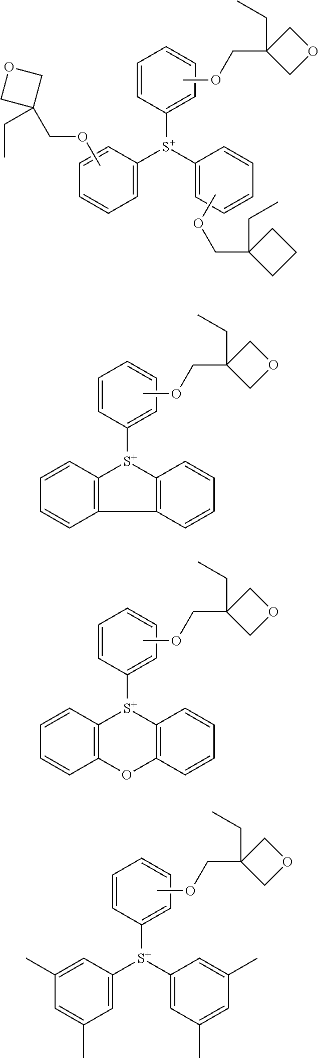

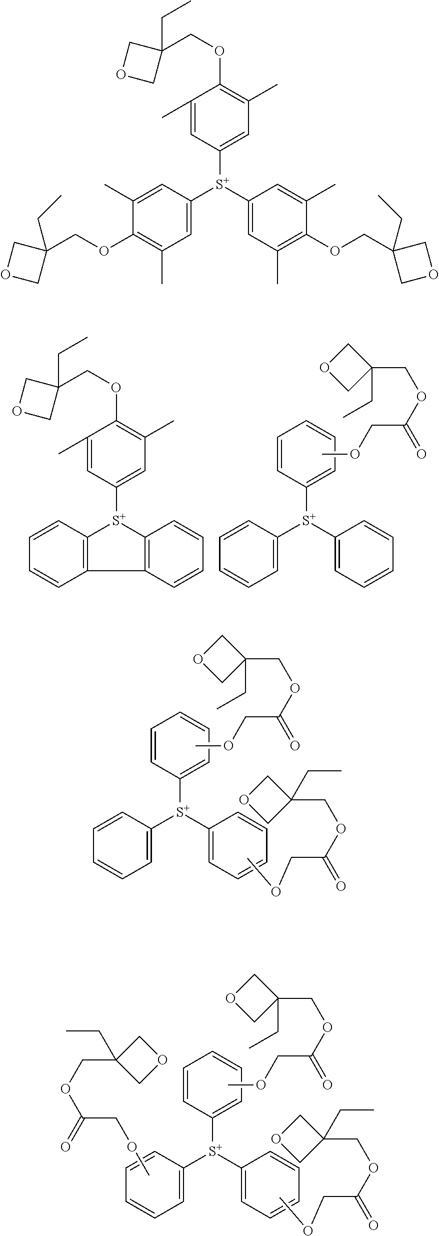

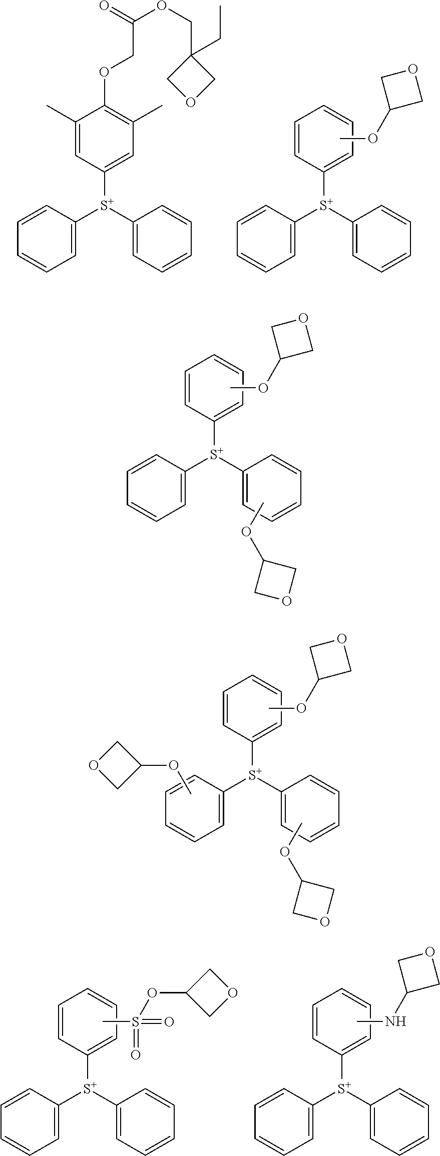

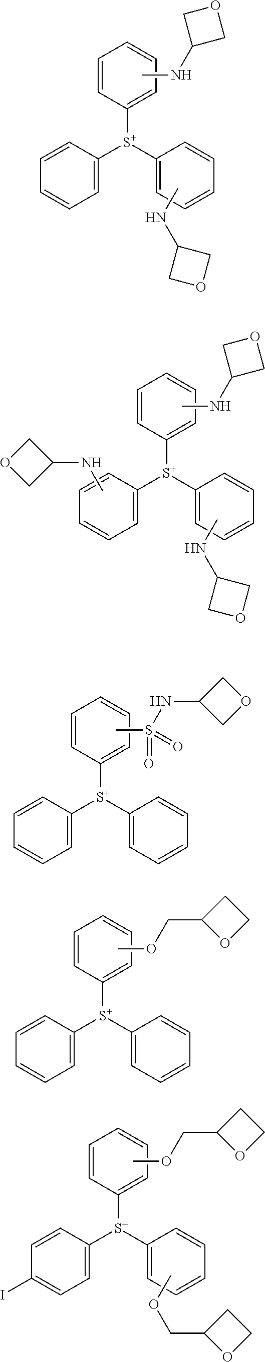

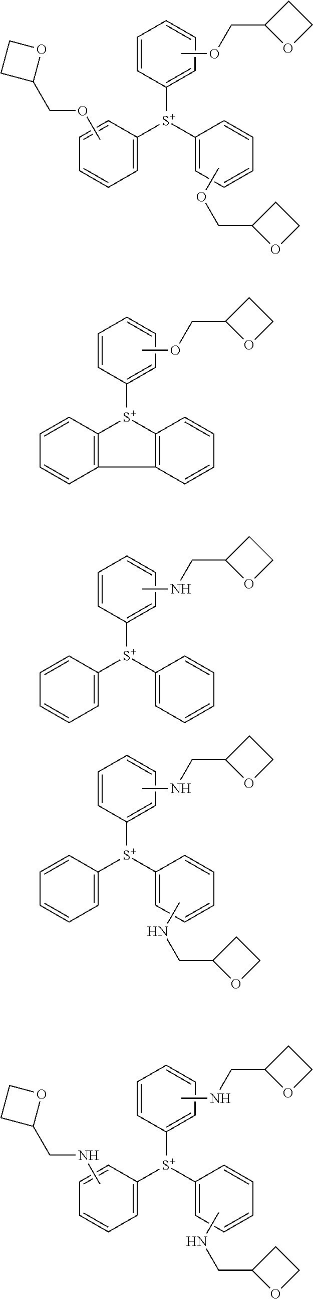

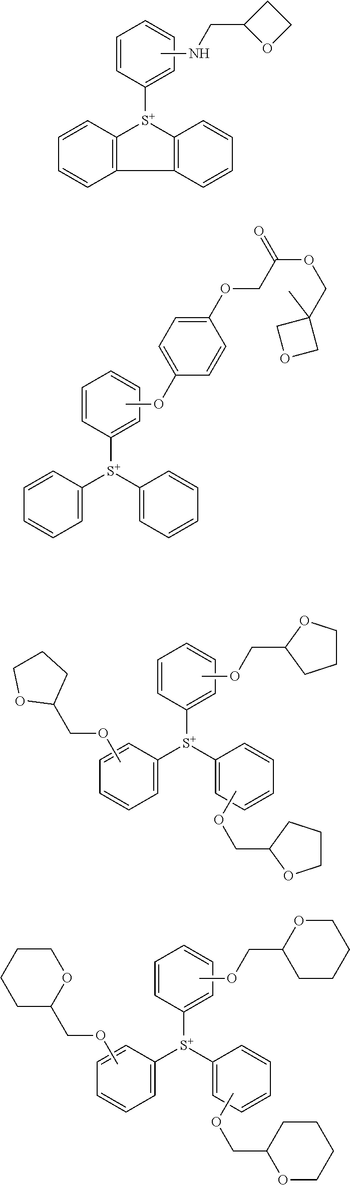

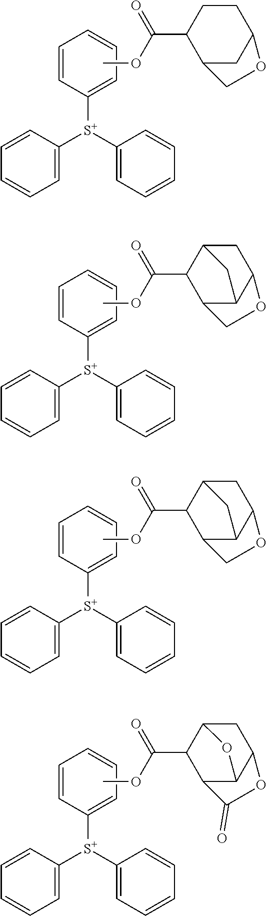

In formula (1). X⁻ is a counter anion. The preferred counter anion is selected from halide ions, nitrate ions, hydrogensulfate ions, hydrogencarbonate ions, borate ions, hexafluorophosphate ions, hexafluoroantimonate ions and anions having the formulae (X-1) to (X-7).

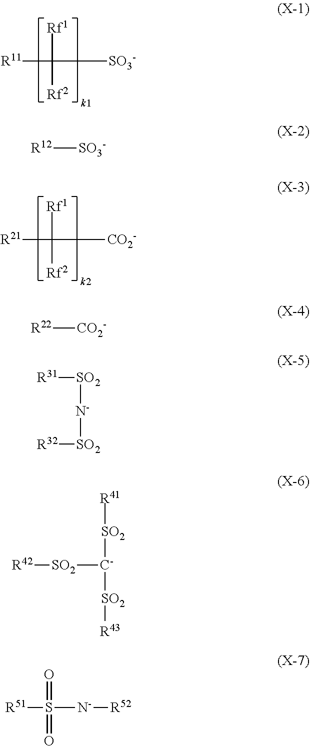

Suitable borate ions include tetrafluoroborate, tetraphenylborate, and tetrakis(pentafluorophenyl) borate ions.

In formulae (X-1) and (X-3), k1 and k2 are each independently an integer of 1 to 4. Rf¹ and Rf² are each independently hydrogen, fluorine or a C₁-C₆ fluorinated alkyl group. Not all Rf¹ and Rf² are hydrogen at the same time.

In formula (X-1), R¹¹ is hydrogen, halogen, hydroxy, or a C₁-C₄₀ hydrocarbyl group which may contain a heteroatom.

In formula (X-2), R¹² is hydrogen, halogen, hydroxy, or a C₁-C₄₀ hydrocarbyl group which may contain a heteroatom, exclusive of a hydrocarbyl group in which hydrogen on α- or β-carbon relative to the sulfo group is substituted by fluorine or fluoroalkyl.

In formula (X-3), R²¹ is hydrogen, halogen, hydroxy, or a C₁-C₄₀ hydrocarbyl group which may contain a heteroatom.

In formula (X-4), R²² is hydrogen, halogen, hydroxy, or a C₁-C₄₀ hydrocarbyl group which may contain a heteroatom, exclusive of a hydrocarbyl group in which hydrogen on α- or β-carbon relative to the carboxy group is substituted by fluorine or fluoroalkyl.

In formula (X-5), R³¹ and R³² are each independently a C₁-C₄₀ hydrocarbyl group which may contain a heteroatom.

In formula (X-6), R⁴¹ to R⁴³ are each independently a C₁-C₄₀ hydrocarbyl group which may contain a heteroatom.

In formula (X-7), R⁵¹ is fluorine or a C₁-C₁₀ fluorinated hydrocarbyl group which may contain hydroxy, ether bond or ester bond. R⁵² is hydrogen or a C₁-C₂₀ hydrocarbyl group which may contain hydroxy, ether bond or ester bond. R⁵¹ and R⁵² may bond together to form a ring with the atoms to which they are attached.

As the anion X, preference is given to halide ions, nitrate ions, and anions having formulae (X-1) to (X-7), especially halide ions, nitrate ions, and anions having formulae (X-2), (X-4) and (X-6).

The C₁-C₄₀ hydrocarbyl group represented by R¹¹, R¹², R²¹, R²², R³¹, R³², R⁴¹, R⁴² and R⁴³ may be saturated or unsaturated and straight, branched or cyclic. Examples thereof include C₁-C₄₀ alkyl groups such as methyl, ethyl, propyl, isopropyl, n-butyl, sec-butyl, tert-butyl, tert-pentyl, n-pentyl, n-hexyl, n-octyl, 2-ethylhexyl, n-nonyl and n-decyl; C₃-C₄₀ cyclic saturated hydrocarbyl groups such as cyclopentyl, cyclohexyl, cyclopentylmethyl, cyclopentylethyl, cyclopentylbutyl, cyclohexylmethyl, cyclohexylethyl, cyclohexylbutyl, norbornyl, tricyclo [5.2.1.0^{2.6}]decyl, adamantyl, and adamantylmethyl; C₆-C₄₀ aryl groups such as phenyl, naphthyl, and anthracenyl; and combinations thereof. In the hydrocarbyl group, some or all hydrogen may be substituted by a moiety containing a heteroatom such as oxygen, sulfur, nitrogen or halogen, or some constituent —CH₂— may be replaced by a moiety containing a heteroatom such as oxygen, sulfur or nitrogen, so that the group may contain a hydroxy, cyano, halogen, carbonyl, ether bond, thioether bond, ester bond, sulfonate ester bond, carbonate bond, carbamate bond, lactone ring, sultone ring or carboxylic anhydride (—C(═O)—O—C(═O)—).

The C₁-C₁₀ fluorinated hydrocarbyl group represented by R⁵¹ is a C₁-C₁₀ hydrocarbyl group in which some or all hydrogen atoms are substituted by fluorine. The C₁-C₁₀ hydrocarbyl group may be saturated or unsaturated and straight, branched or cyclic, and examples thereof are as exemplified above for the C₁-C₄₀ hydrocarbyl group represented by R¹¹, R¹², R²¹, R²², R³¹, R³², R⁴¹, R⁴² and R⁴³, but of 1 to 10 carbon atoms.

The C₁-C₂₀ hydrocarbyl group represented by R⁵² may be saturated or unsaturated and straight, branched or cyclic, and examples thereof are as exemplified above for the C₁-C₄₀ hydrocarbyl group represented by R¹¹, R¹², R²¹, R²², R³¹, R³², R⁴¹, R⁴² and R⁴³, but of 1 to 20 carbon atoms.

The anion having any one of formulae (X-1) to (X-7) may possess a C₂-C₂₀ hydrocarbyl group which contains a polymerizable functional group in its structure and may contain a heteroatom. Examples thereof are the same as exemplified above for the group A¹ in formula (1).

Examples of the anion having formula (X-1) are shown below, but not limited thereto. Herein Rf¹ is as defined above.

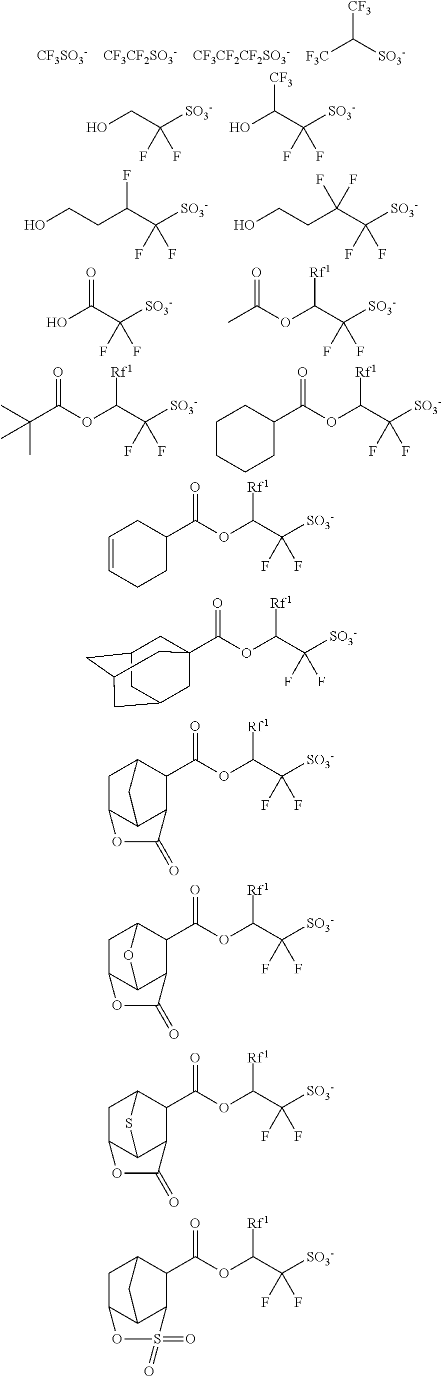

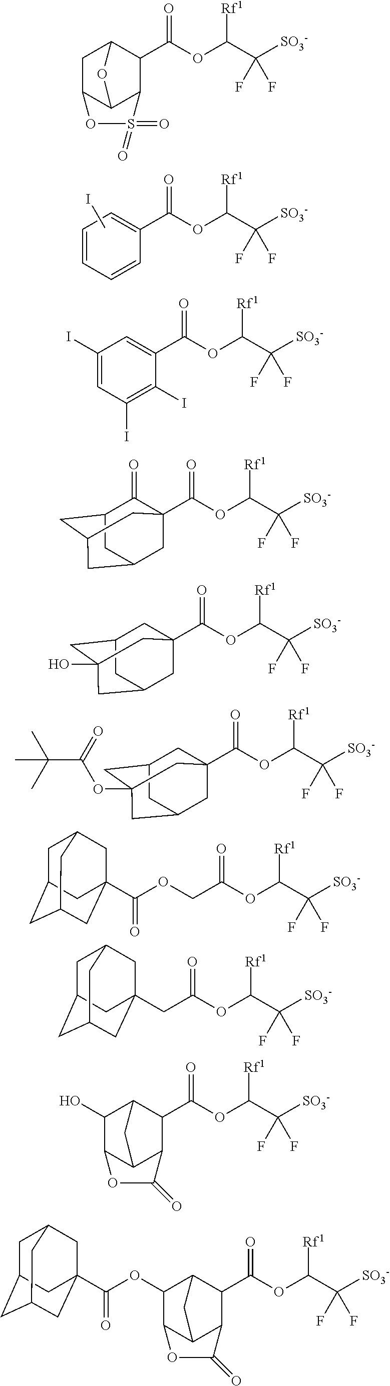

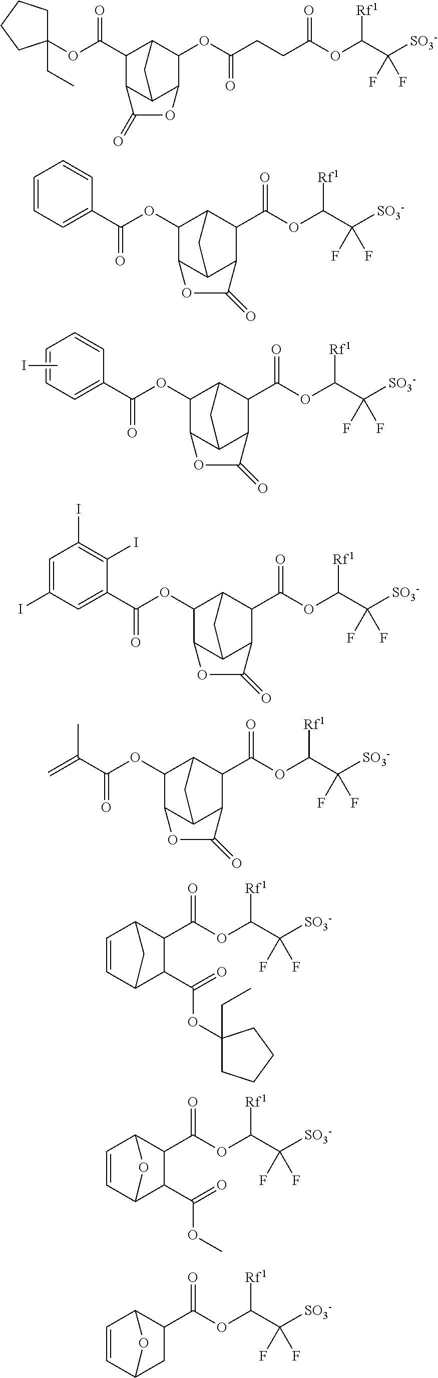

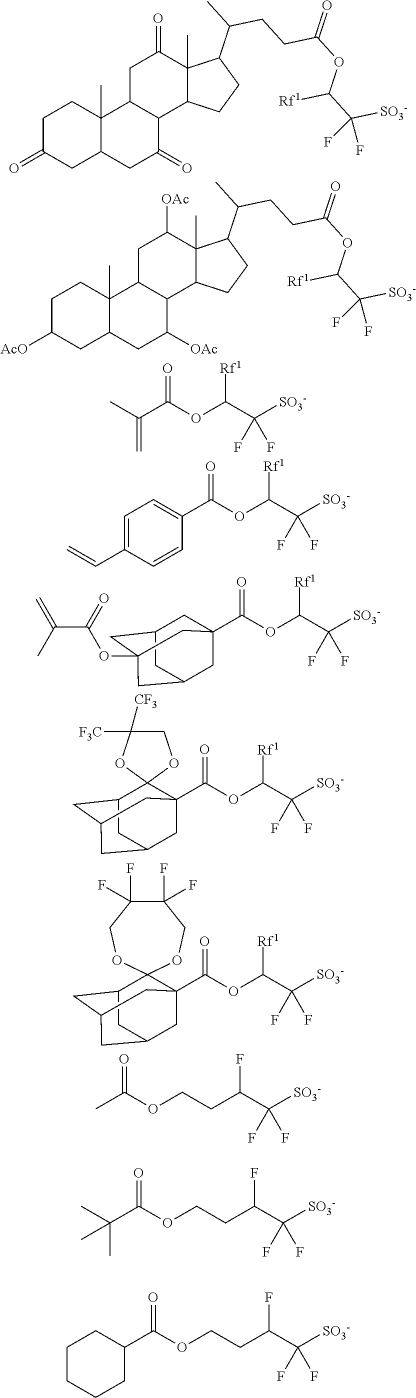

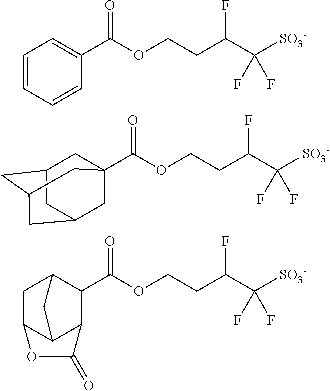

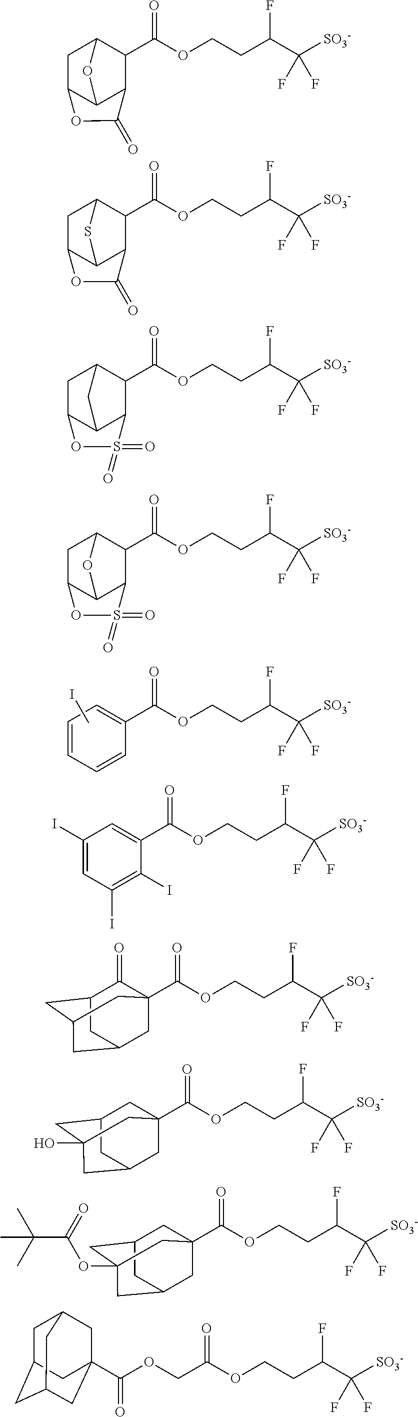

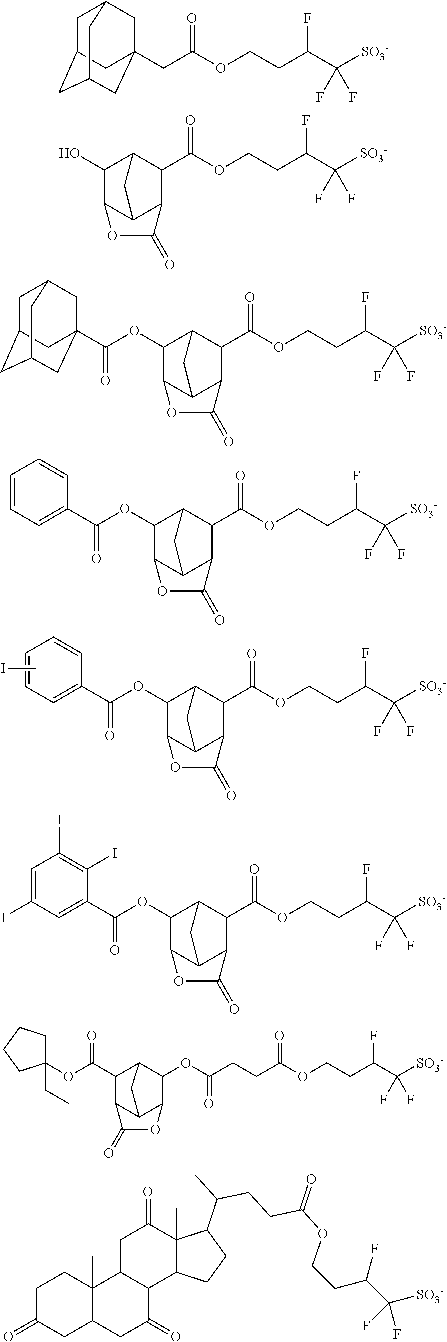

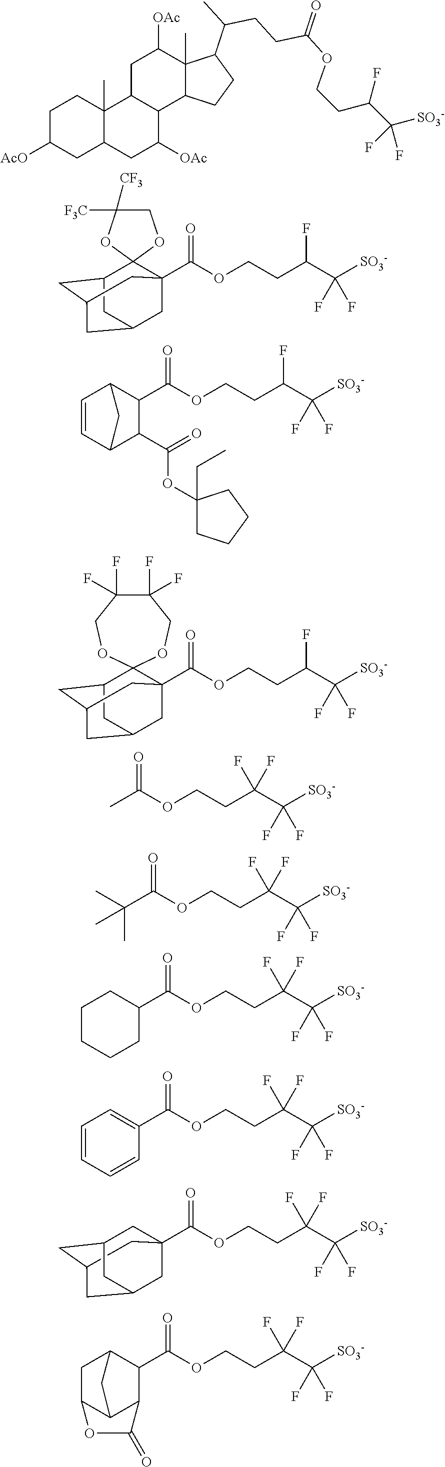

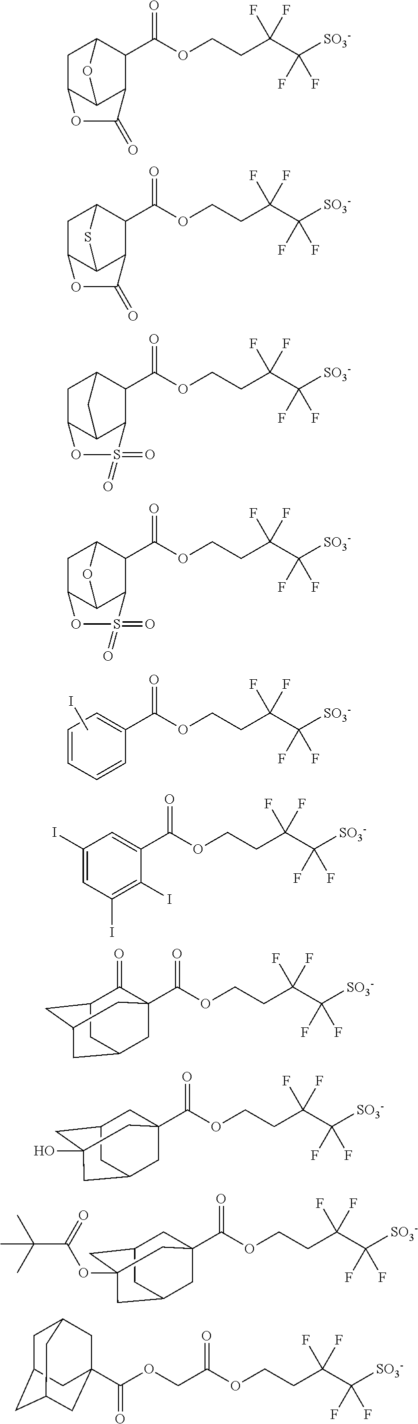

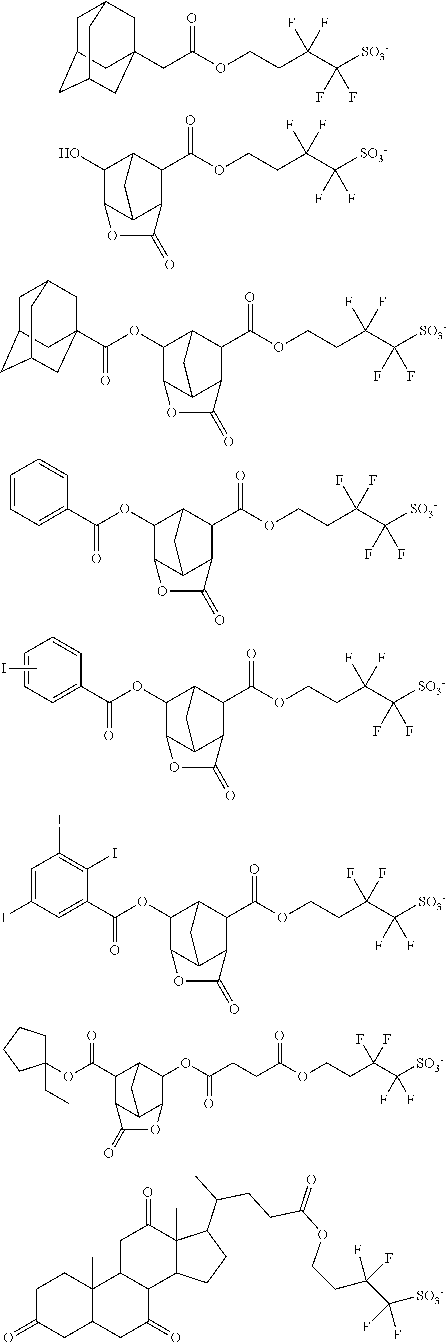

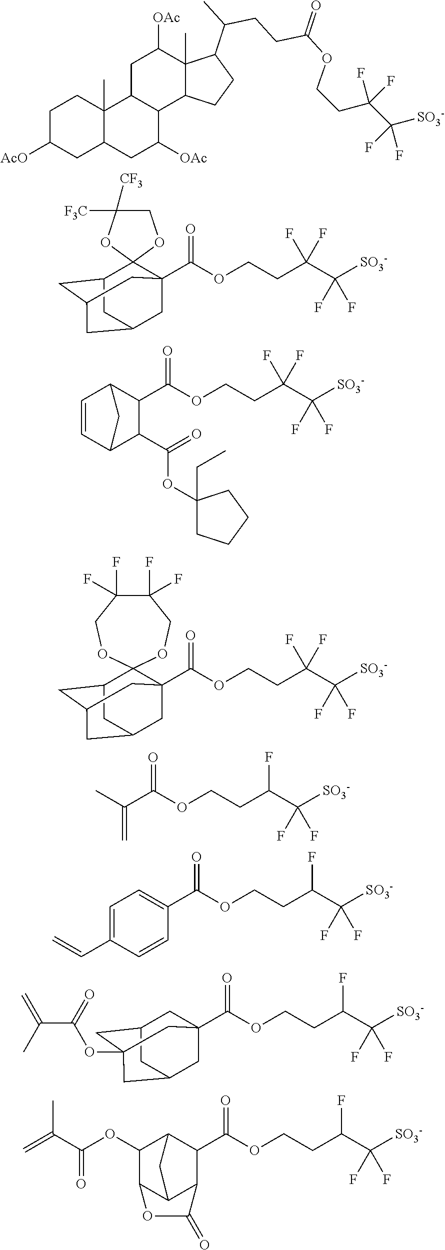

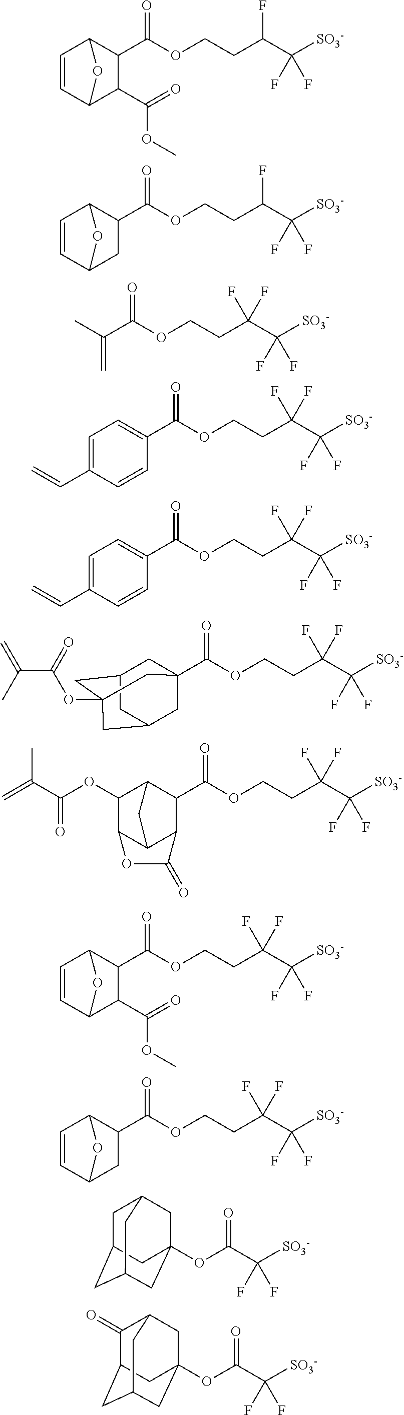

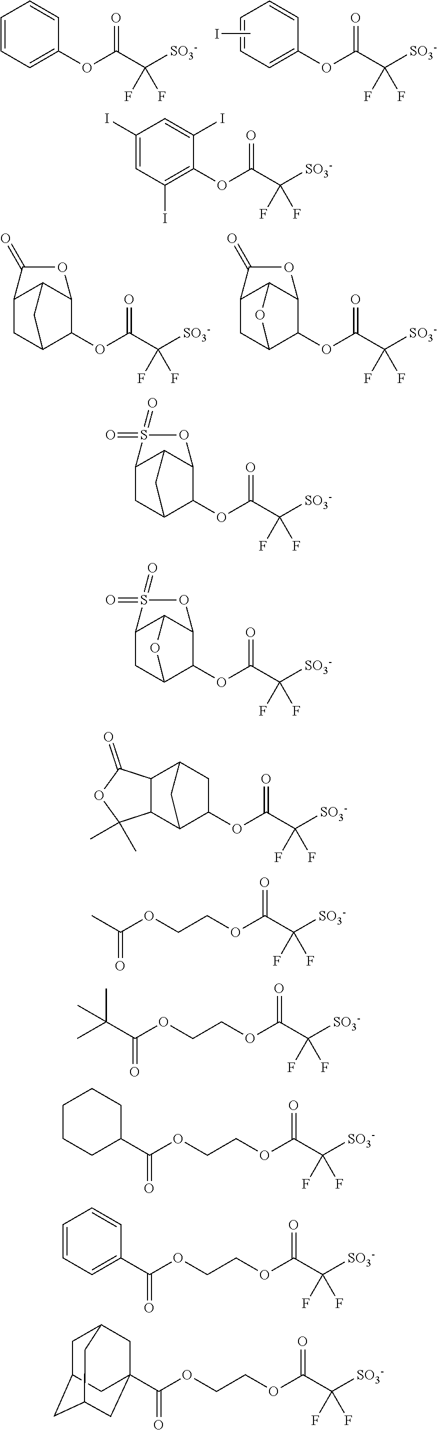

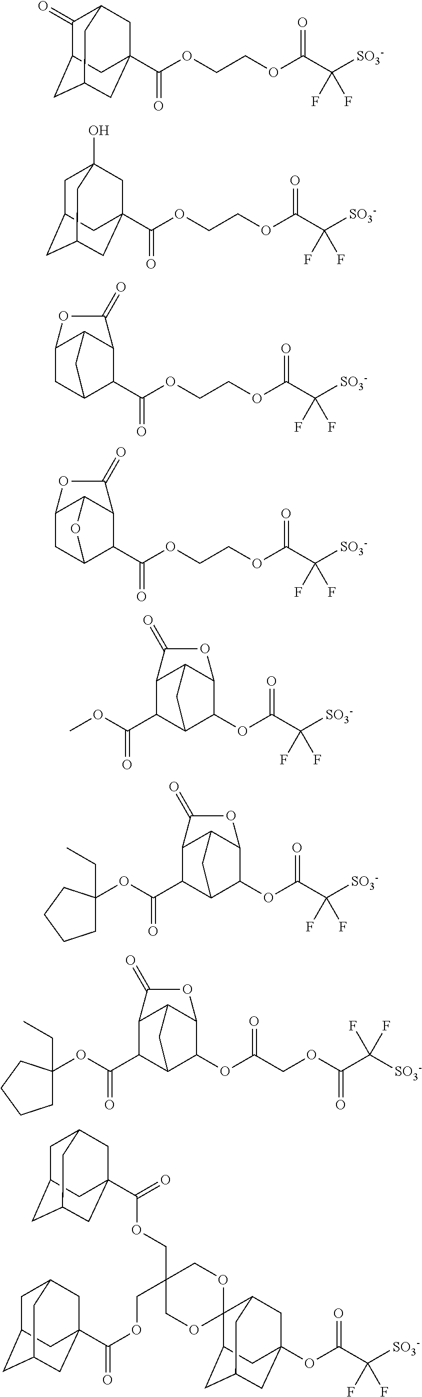

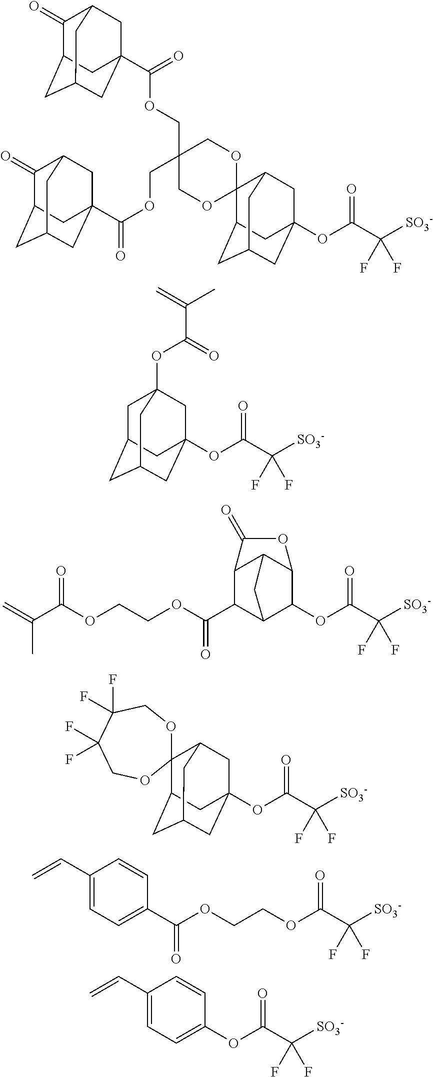

Examples of the anion having formula (X-2) are shown below, but not limited thereto.

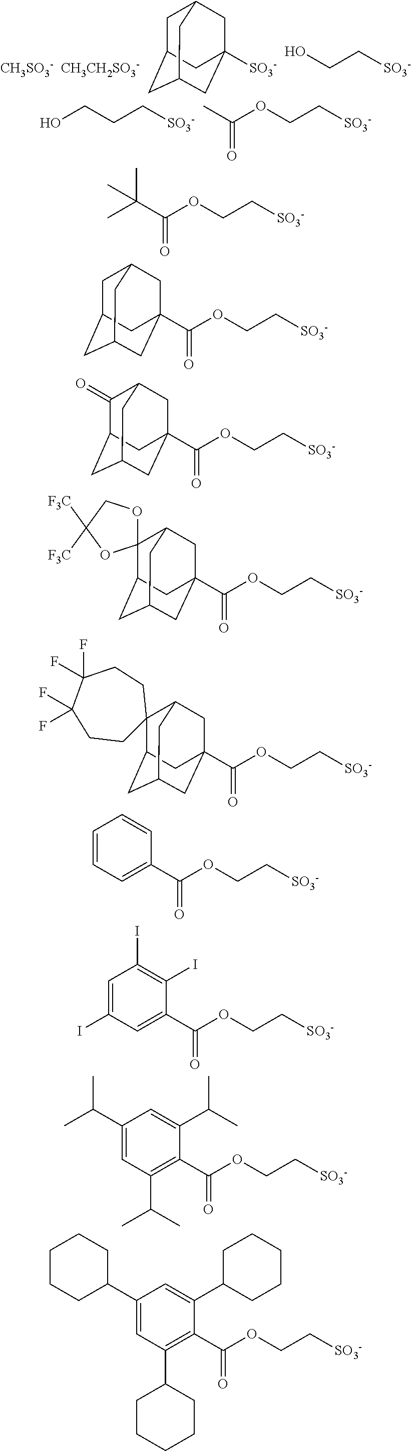

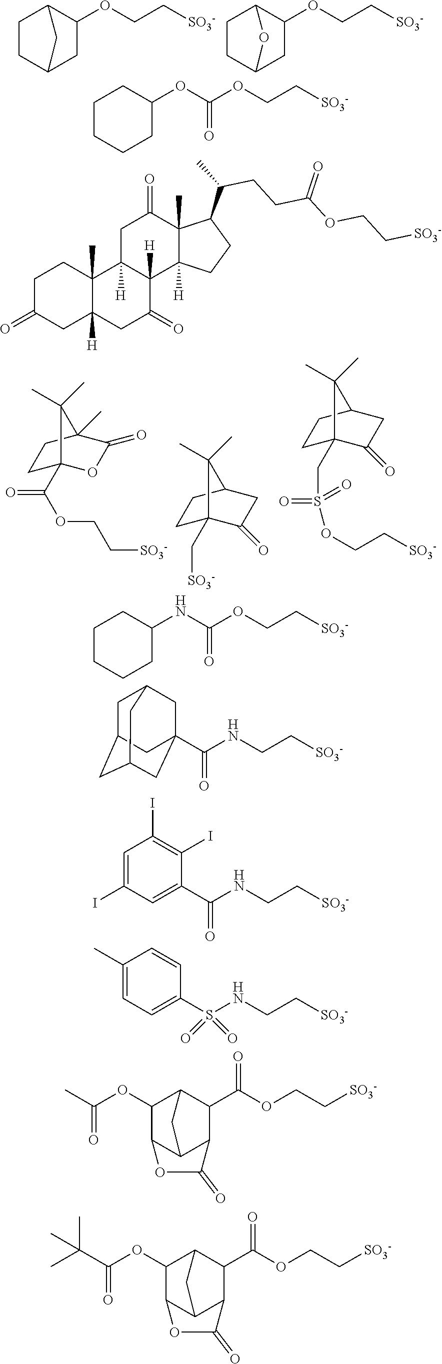

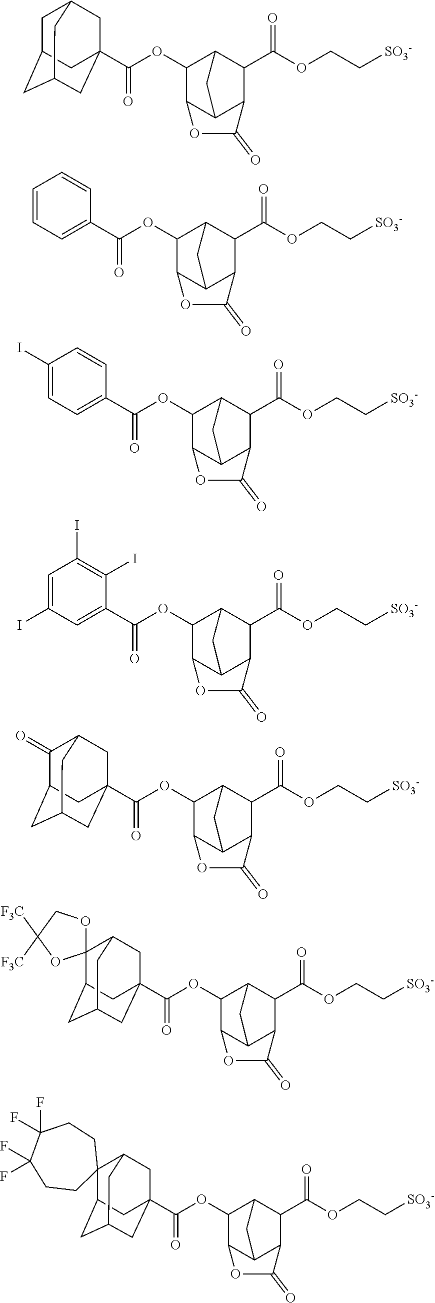

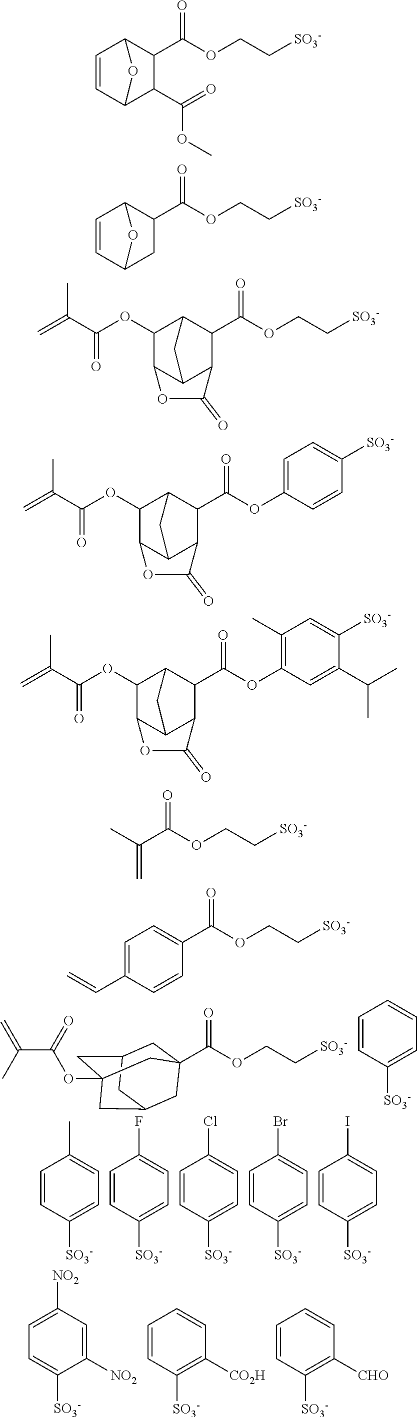

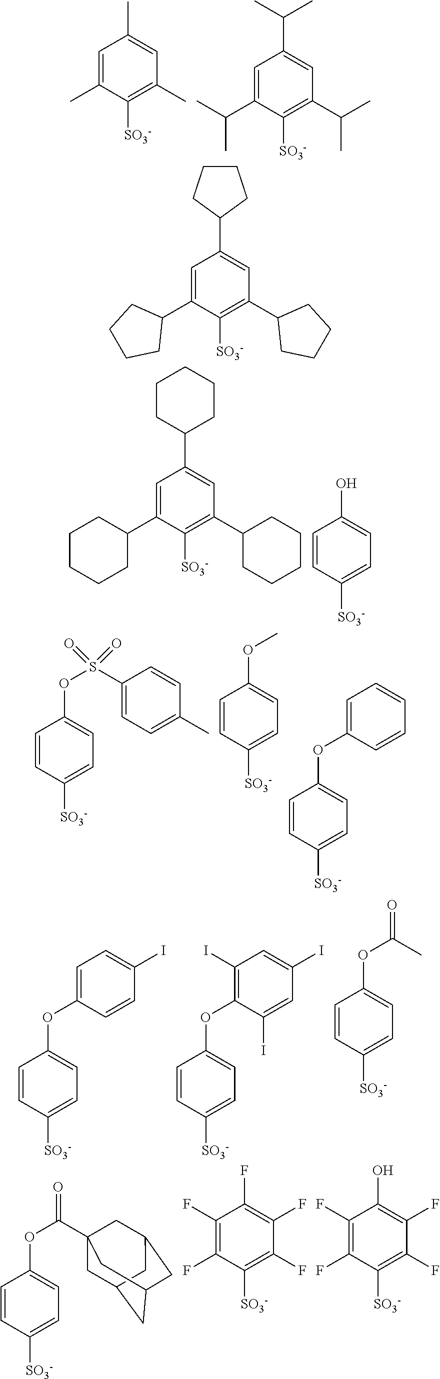

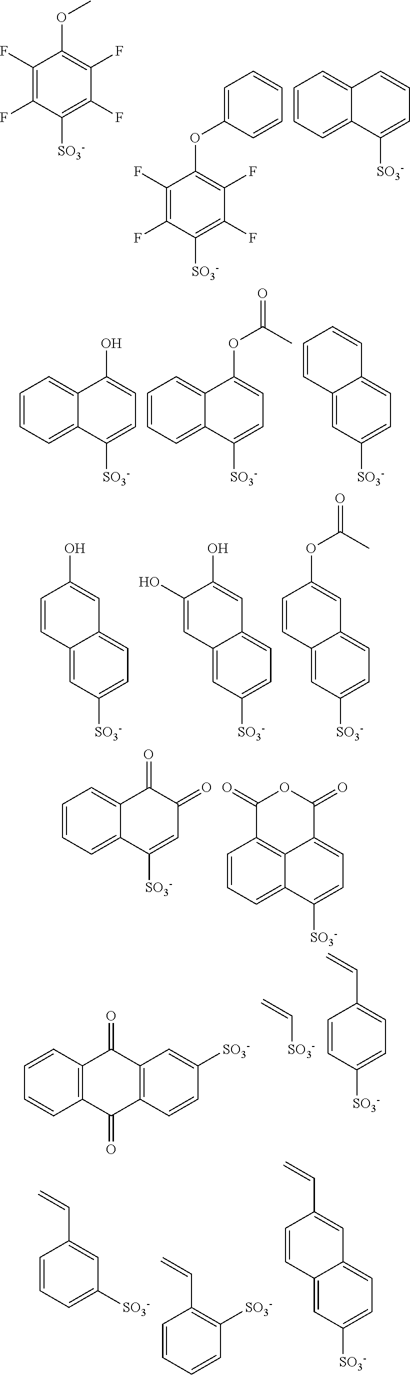

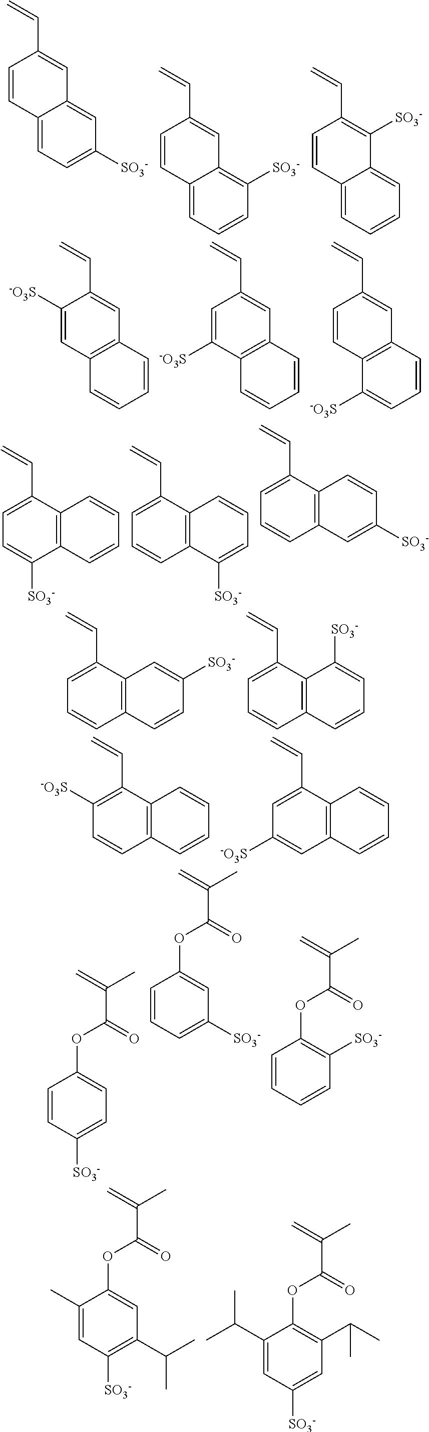

Examples of the anion having formula (X-3) are shown below, but not limited thereto.

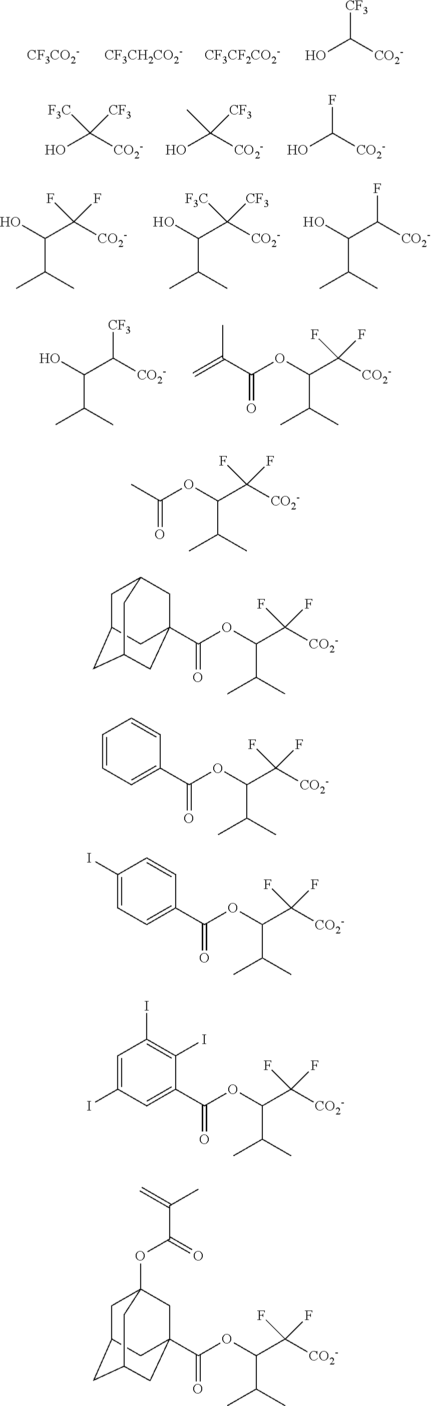

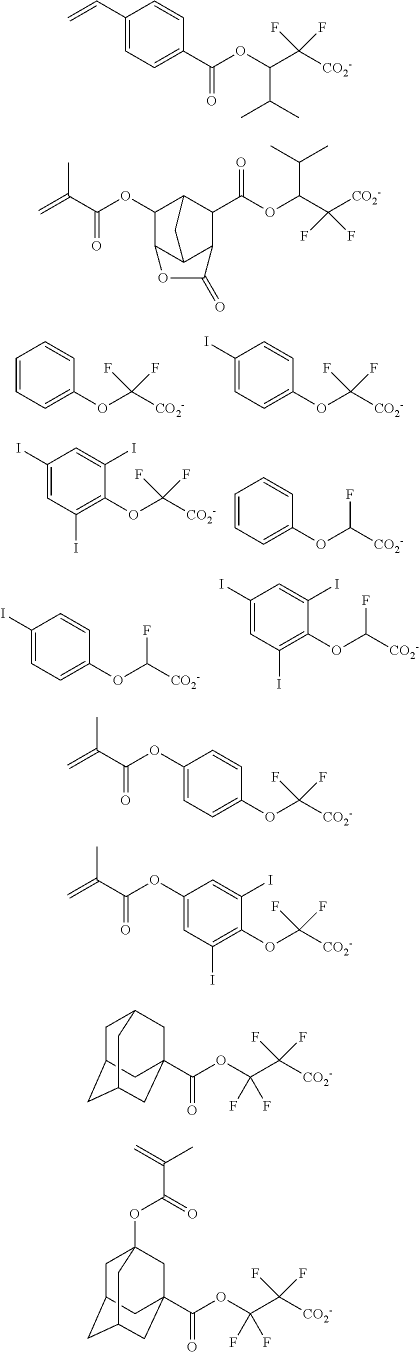

Examples of the anion having formula (X-4) are shown below, but not limited thereto.

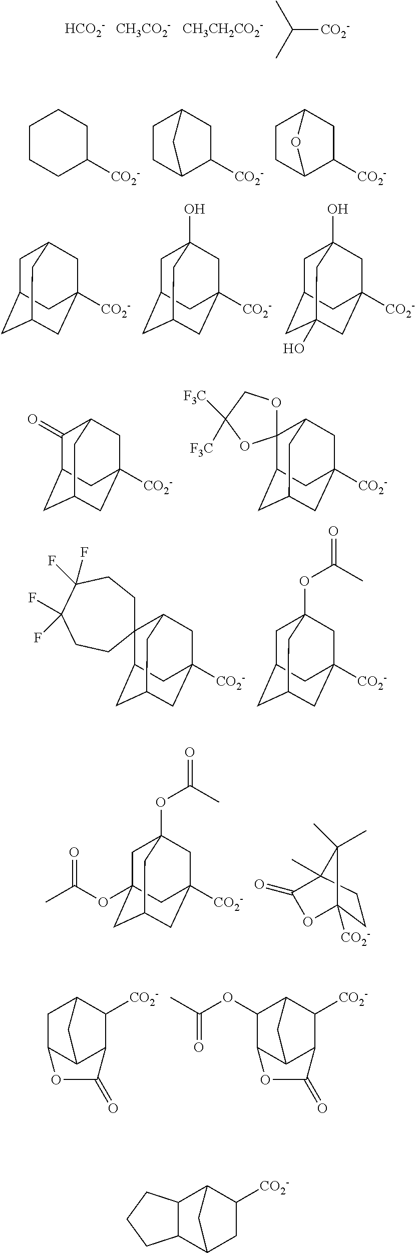

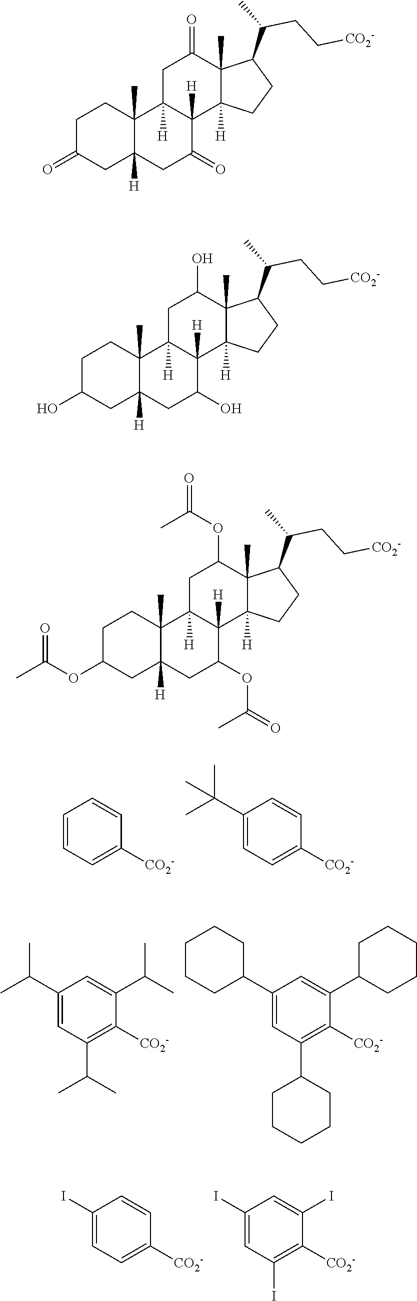

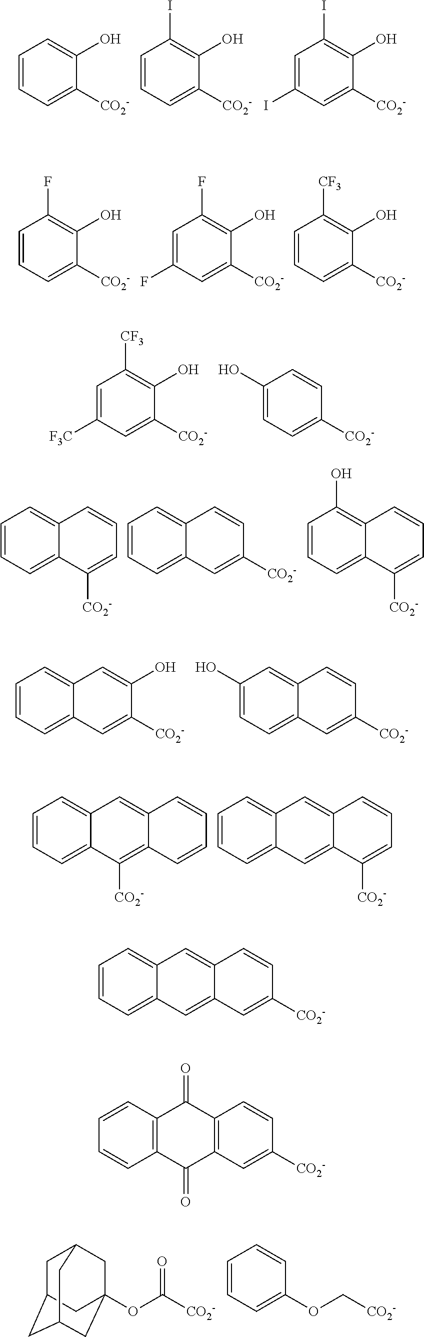

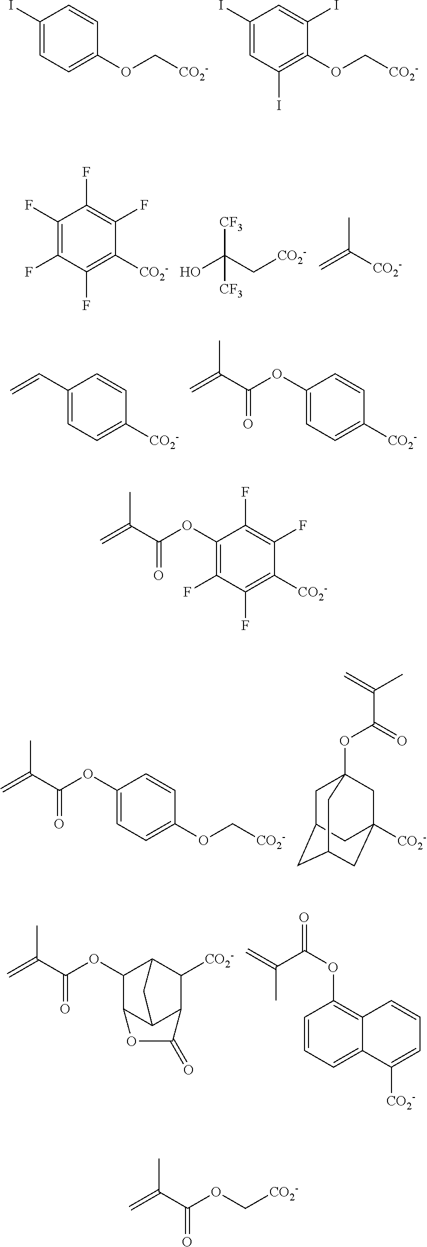

Examples of the anion having formula (X-5) are shown below, but not limited thereto.

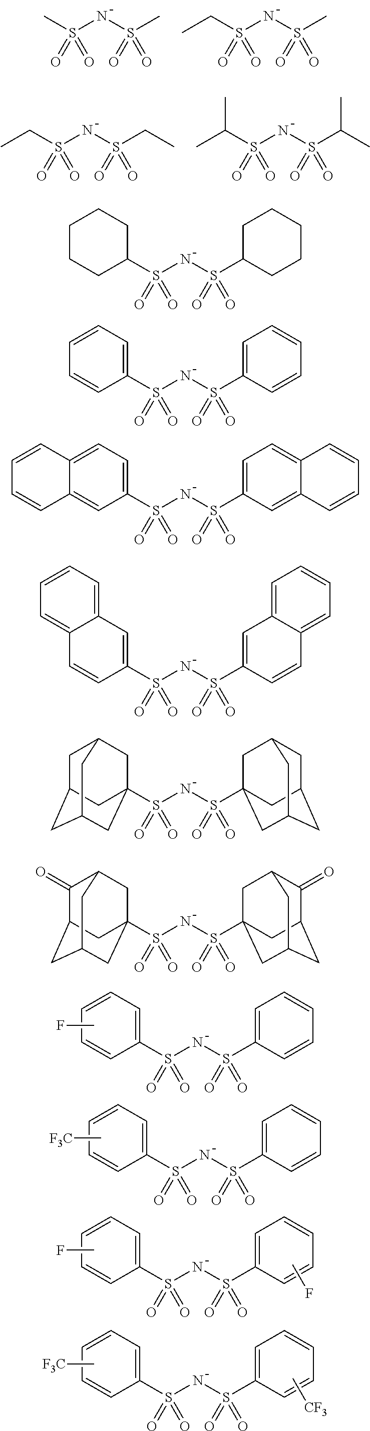

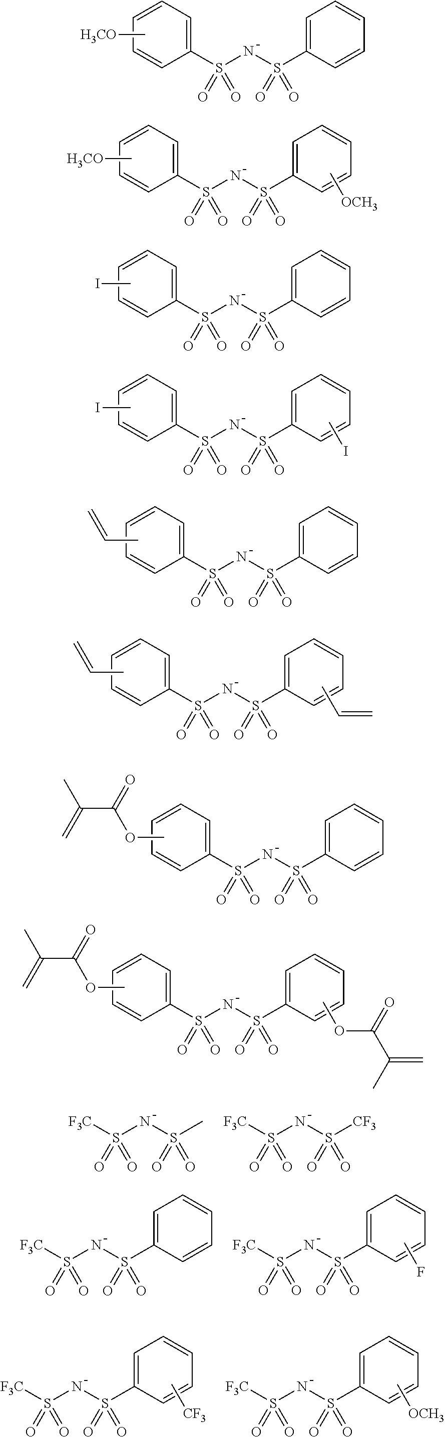

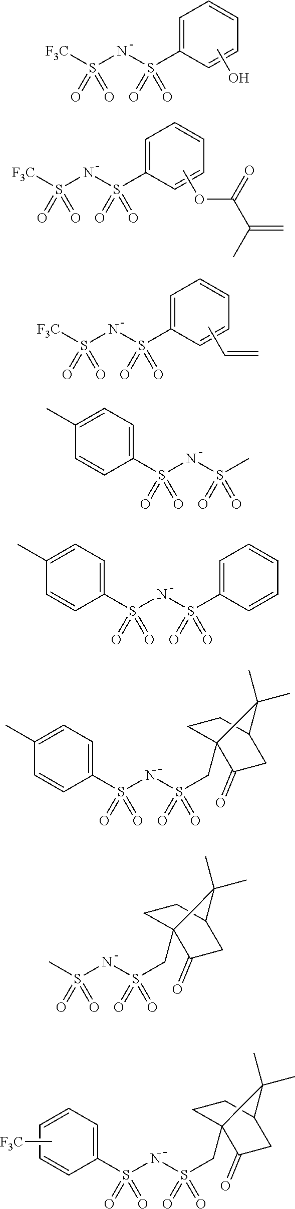

Examples of the anion having formula (X-6) are shown below, but not limited thereto.

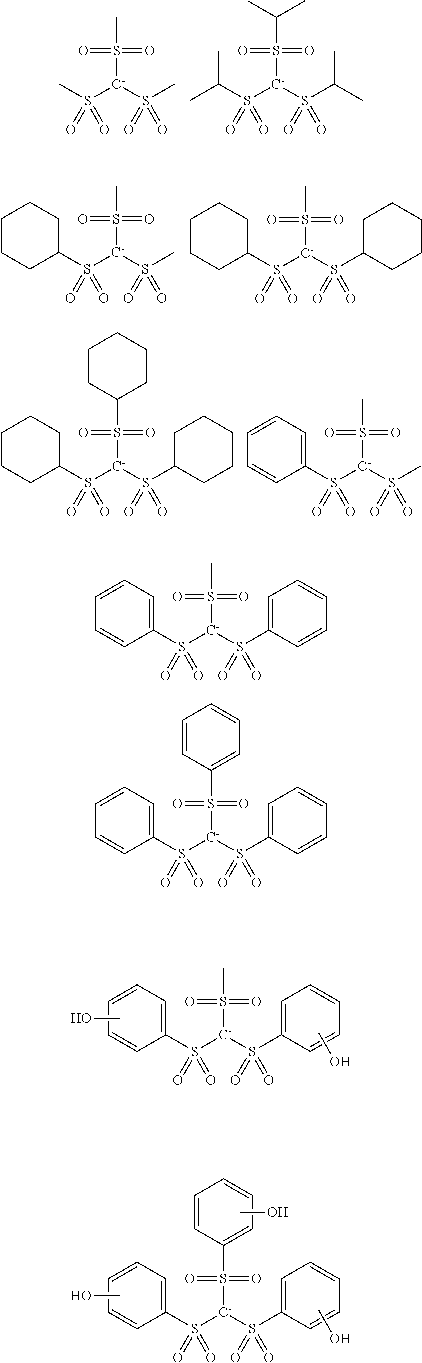

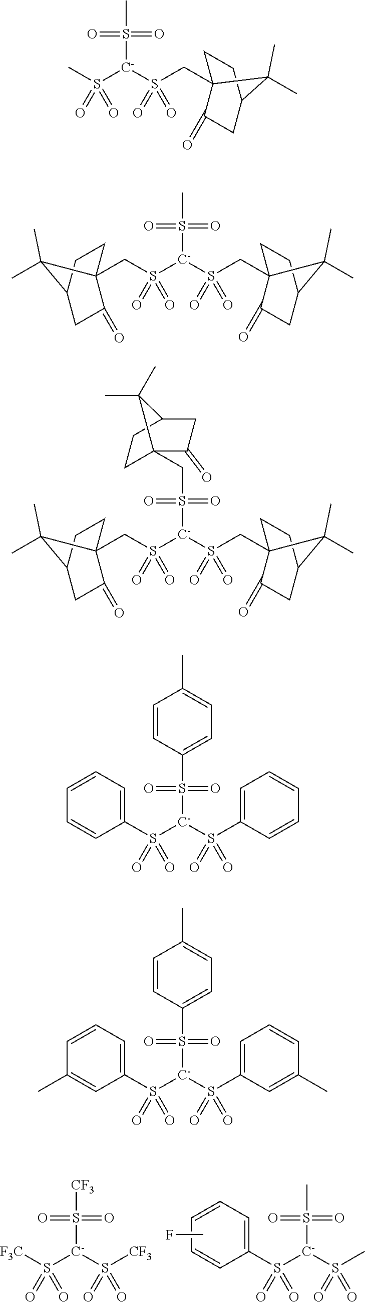

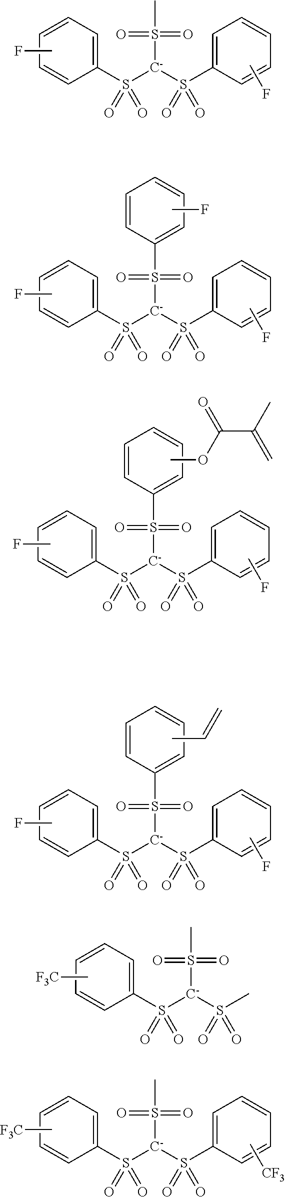

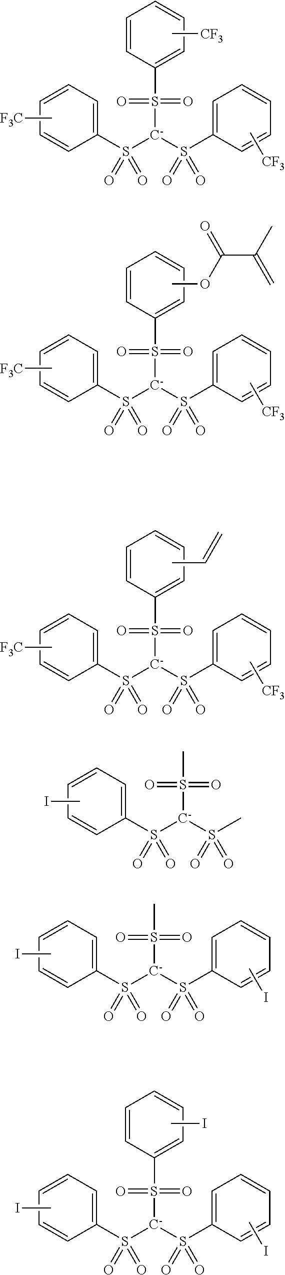

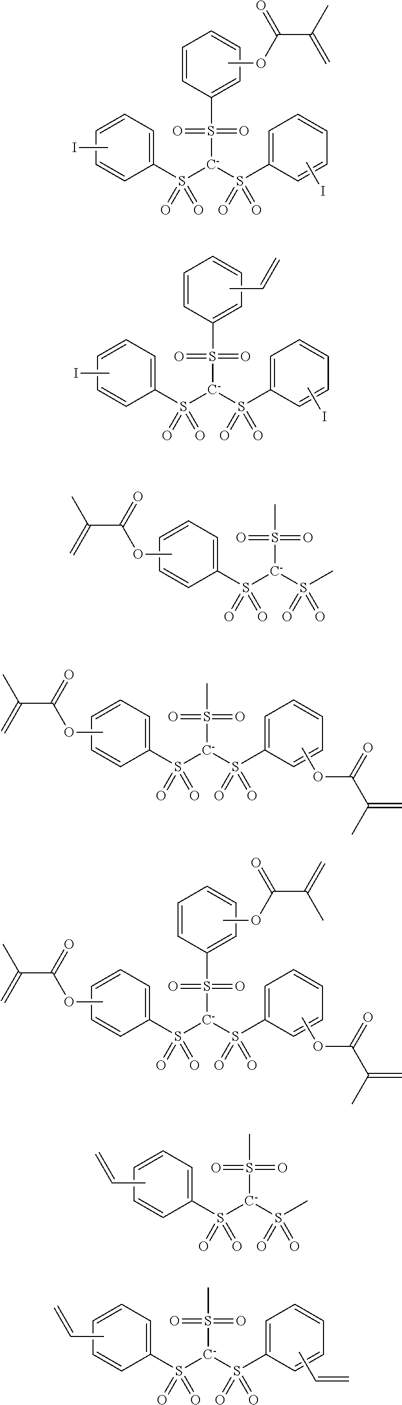

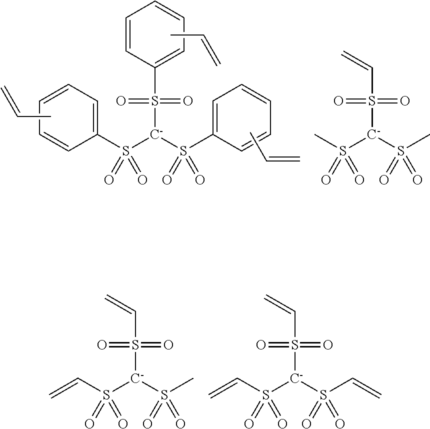

Examples of the anion having formula (X-7) are shown below, but not limited thereto.

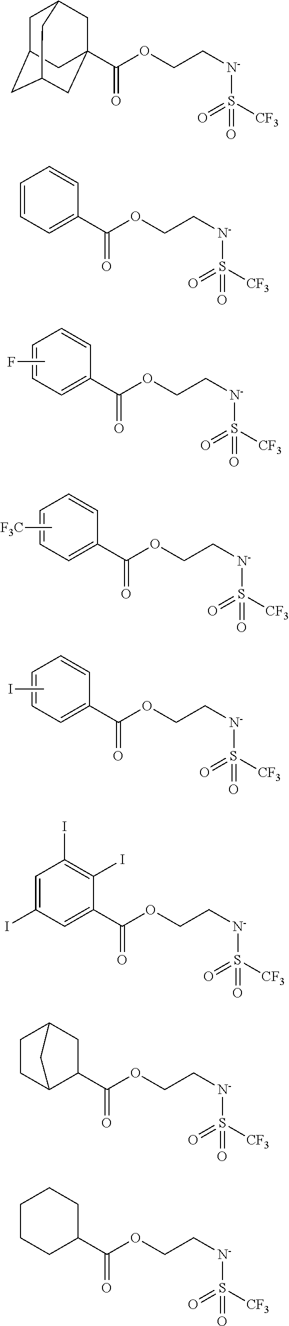

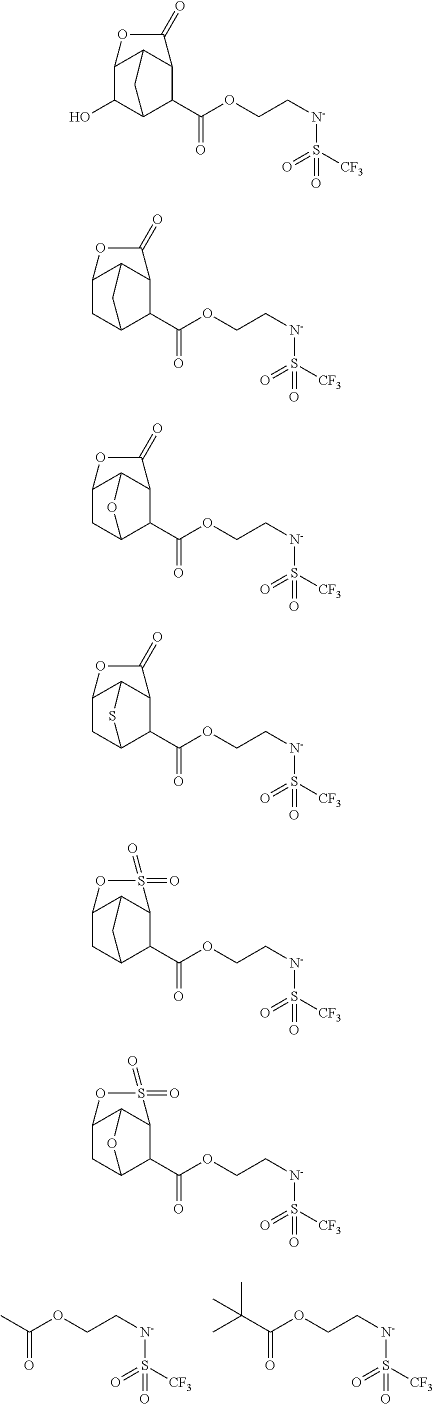

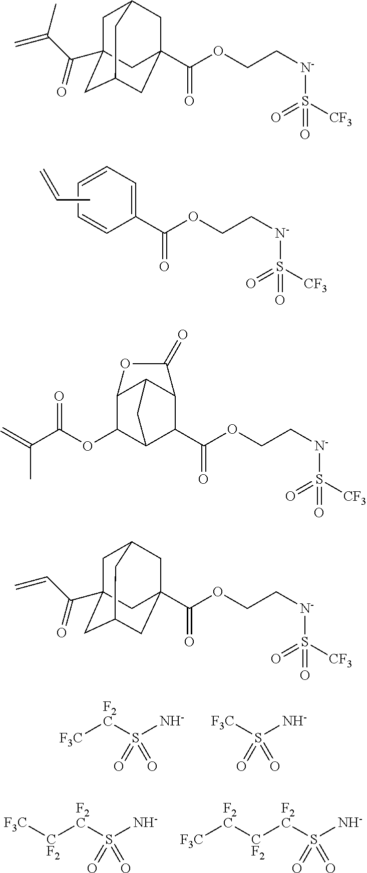

Suitable examples of the sulfonium salt having formula (1) include arbitrary combinations of anions with cations, both as exemplified above.

The sulfonium salt having formula (1) may be synthesized by a suitable combination of well-known organic chemistry procedures. One exemplary procedure is by mixing an onium salt intermediate having a desired cation with an onium salt intermediate having a desired anion, followed by ion exchange reaction. The ion exchange reaction may be performed by a well-known technique, for example, with reference to JP-A 2007-145797.

The cyclic ether site-containing onium salt may be used alone or in admixture of two or more.

### [Organic Solvent]

The molecular resist composition of the invention contains an organic solvent. The solvent used herein is not particularly limited as long as it dissolves the cyclic ether site-containing onium salt and is able to form a film. Suitable organic solvents include ketones such as cyclohexanone and methyl-2-n-pentyl ketone; alcohols such as 3-methoxybutanol, 3-methyl-3-methoxybutanol, 1-methoxy-2-propanol, 1-ethoxy-2-propanol, and diacetone alcohol (DAA); ethers such as propylene glycol monomethyl ether, ethylene glycol monomethyl ether, propylene glycol monoethyl ether, ethylene glycol monoethyl ether, propylene glycol dimethyl ether, and diethylene glycol dimethyl ether; esters such as propylene glycol monomethyl ether acetate (PGMEA), propylene glycol monocthyl ether acetate, ethyl lactate, ethyl pyruvate, butyl acetate, methyl 3-methoxypropionate, ethyl 3-ethoxypropionate, tert-butyl acetate, tert-butyl propionate, and propylene glycol mono-tert-butyl ether acetate; and lactones such as γ-butyrolactone (GBL).

Of these, 1-ethoxy-2-propanol, PGMEA, cyclohexanone, DAA, GBL, and mixtures thereof are preferred.

An appropriate amount of the organic solvent used is 200 to 5,000 parts by weight per 100 parts by weight of the cyclic ether site-containing onium salt. The organic solvent may be used alone or in admixture.

The molecular resist composition of the invention is characterized by comprising the cyclic ether site-containing onium salt as a main component and the organic solvent, and being free of a base polymer. When a resist film formed from the molecular resist composition is exposed to EB or EUV, it forms a negative tone pattern as a result of the resist film in the exposed region turning insoluble in alkaline developer. As used herein, the term “base polymer” refers to a polymer which is a main component of polymeric resist compositions and adapted to change its solubility in developer under the action of an acid generated from an acid generator.

Resist compositions of conventional design, that is, comprising a multi-component polymer as a main component or base polymer, a photoacid generator, a quencher and other additives lack the resolution of thin lines and are degraded in LWR and CDU under the influence of the polymer having a large molecular size.

In contrast, the molecular resist composition which does not contain a multi-component polymer manifests a high contrast as a result of the photo-decomposition of the onium salt and a concomitant solubility change. The resist composition whose main component is a low-molecular-weight compound having a small molecular size is able to form extremely small-size patterns by the EB or EUV lithography. Additionally, LWR and CDU are improved.

Although the reason why the molecular resist composition manifests a high contrast and resolution as well as improved LWR and CDU is not well understood, the presumption is described below. In the molecular resist composition, a structural change as a result of photo-reaction of the cyclic ether site-containing onium salt as the main component becomes the driving force for contrast enhancement. Specifically, the onium salt which is an ionic compound becomes more hydrophobic and insoluble in an alkaline developer as it turns to a non-ionic structure. In addition, the inclusion of a cyclic ether site is essential. This cyclic ether site incurs crosslinking reaction by utilizing as a catalyst the acid which is generated from the anion along with photo-decomposition of the onium salt. Particularly in the case of an oxirane or oxetane ring having a very high reactivity, crosslinking reaction takes place more outstandingly. A molecular weight buildup by crosslinking further promotes insolubilization in alkaline developer, leading to a higher contrast. The composition turns insoluble not only in alkaline developers, but also in organic solvent developers, achieving a contrast in negative mode.

Some molecular resist compositions are known in the prior art. These resist compositions are difficultly improved in LWR and CDU because a variety of components are involved and in-film uniformity is poor. Particularly in the micropatterning process using EUV radiation providing a small number of photons, the in-film uniformity has a very large impact on the outcome of lithography. For example, the molecular resist composition of JP-A 2013-205521 contains essentially a calix resorcinarene compound as a base and a photoacid generator, and optionally a basic compound. In the case of a negative tone molecular resist composition, a crosslinker is also necessary. In contrast, the cyclic ether site-containing onium salt in the inventive molecular resist composition possesses both the functions of photoacid generator and base, and only a quencher (amine compound or onium salt) is contained as another component if necessary.

The inventive molecular resist composition is of simple design using a low molecular weight base without a need for base polymer, which is not found in prior art molecular resist compositions. Since the molecular resist composition manifests a high contrast by virtue of this design and improved LWR and CDU due to satisfactory in-film uniformity, it is fully effective for forming small-size patterns.

### [Amine Compound]

The molecular resist composition of the invention may contain an amine compound. Inclusion of an amine compound enables to control crosslinking reaction and to adjust sensitivity, resolution and LWR. Suitable amine compounds include primary, secondary, and tertiary aliphatic amines, mixed amines, aromatic amines, heterocyclic amines, nitrogen-containing compounds with carboxyl group, nitrogen-containing compounds with sulfonyl group, nitrogen-containing compounds with hydroxyl group, nitrogen-containing compounds with hydroxyphenyl group, alcoholic nitrogen-containing compounds, amide derivatives, imide derivatives, and carbamate derivatives. Preferred are primary, secondary, and tertiary amine compounds, specifically amine compounds having a hydroxy, ether bond, ester bond, lactone ring, cyano, or sulfonate ester bond as described in JP-A 2008-111103, paragraphs [0146]-[0164], and compounds having a carbamate group as described in JP 3790649.

When contained, the amine compound is preferably used in an amount of 0.05 to 80 parts by weight per 100 parts by weight of the cyclic ether site-containing onium salt. The amine compound may be used alone or in admixture.

### [Surfactant]

Although the molecular resist composition does not contain a polymer component that functions as a base polymer, the composition may contain a polymer component which is used as an additive (i.e., not a main component) like a polymer serving as a surfactant as long as it does not inhibit pattern formation by the cyclic ether site-containing onium salt. Suitable surfactants include FC-4432 and FC-4430 (3M), PF636, PF656, PF6320, and PF6520 (Omnova Solutions Inc.). When the molecular resist composition contains a surfactant, the amount of the surfactant is preferably 0.001 to 20 parts, more preferably 0.1 to 10 parts by weight per 100 parts by weight of the cyclic ether site-containing onium salt. The surfactant may be used alone or in admixture.

### [Other Onium Salt]

The molecular resist composition may contain an onium salt other than the cyclic ether site-containing onium salt. The other onium salt is effective for fine adjustment of sensitivity and solubility. Although the structure of the other onium salt is not particularly limited, the preferred cations include sulfonium, iodonium and ammonium cations. The preferred anions are as exemplified above for the anion represented by X⁺ in formula (1). When the molecular resist composition contains the other onium salt, the amount thereof is preferably 0.05 to 80 parts by weight per 100 parts by weight of the cyclic ether site-containing onium salt. The other onium salt may be used alone or in admixture.

### [Process]

Another embodiment of the invention is a pattern forming process using the molecular resist composition defined above. A variety of integrated circuits may be formed from the resist composition using any well-known lithography process. The preferred process includes the steps of applying the molecular resist composition to a substrate to form a resist film thereon, exposing the resist film to high-energy radiation, and developing the exposed resist film in a developer. Any desired steps may be added to the process if necessary.

First, the resist composition is applied to a substrate by a suitable coating technique such as spin coating, roll coating, flow coating, dipping, spraying or doctor coating. The substrate used herein may be a substrate for integrated circuitry fabrication, e.g., Si, SiO2, SiN, SION, TIN, WSi, BPSG, SOG, organic antireflective film, etc. or a substrate for mask circuitry fabrication, e.g., Cr, CrO, CrON, MoSi2, SiO2, etc. The coating is prebaked on a hot plate preferably at a temperature of 60 to 150° C. for 10 seconds to 30 minutes, more preferably at 80 to 120° C. for 30 seconds to 20 minutes. The resulting resist film preferably has a thickness of 0.01 to 2 μm.

Then the resist film is exposed patternwise to high-energy radiation. Examples of the high-energy radiation include UV, deep UV, EB, EUV, X-ray, soft X-ray, excimer laser, Y-ray, and synchrotron radiation. On use of UV, deep UV, EUV, X-ray, soft X-ray, excimer laser, γ-ray or synchrotron radiation, the resist film is exposed directly or through a mask having a desired pattern, preferably in a dose of 1 to 200 mJ/cm², more preferably 10 to 100 mJ/cm². On use of EB, a pattern may be written directly or through a mask having a desired pattern, preferably in a dose of about 0.1 to 2,000 μC/cm², more preferably about 0.5 to 1,000 μC/cm². The molecular resist composition is suitable particularly in micropatterning using KrF excimer laser, ArF excimer laser, EB, EUV, X-ray, soft X-ray, γ-ray or synchrotron radiation, especially EB or EUV.

Since the molecular resist composition is adapted to form a pattern or image via a structural change of the onium salt during exposure, the post-exposure bake (PEB) as is necessary for chemically amplified resist compositions is not always necessary. PEB may be carried out to control the crosslinking reaction at cyclic ether sites. If PEB is involved, the resist film after exposure is baked on a hotplate or in an oven preferably at 30 to 120° C. for 10 seconds to 30 minutes, more preferably at 60 to 100° C. for 30 seconds to 20 minutes.

After the exposure or PEB, the resist film is developed with a developer in the form of an aqueous base solution for 3 seconds to 3 minutes, preferably 5 seconds to 2 minutes by conventional techniques such as dip, puddle and spray techniques. A typical developer is a 0.1 to 10 wt %, preferably 2 to 5 wt % aqueous solution of tetramethylammonium hydroxide (TMAH), tetraethylammonium hydroxide (TEAH), tetrapropylammonium hydroxide (TPAH), or tetrabutylammonium hydroxide (TBAH). In this way, a desired resist pattern is formed on the substrate. Since the molecular resist composition is of negative tone, a negative tone pattern is formed in which the exposed region of the resist film is insolubilized and the unexposed region is dissolved away.

After the development in alkaline developer, the resist film is rinsed with pure water and dried by spin drying. Use of a rinse fluid containing a surfactant or supercritical rinsing with carbon dioxide is effective for reducing the stress applied onto the pattern during drying for thereby preventing pattern collapse.

Alternatively, the molecular resist composition may be subjected to organic solvent development to form a negative tone pattern. The organic solvent used as the developer is preferably selected from 2-octanone, 2-nonanone, 2-heptanone, 3-heptanone, 4-heptanone, 2-hexanone, 3-hexanone, diisobutyl ketone, methylcyclohexanone, acetophenone, methylacetophenone, propyl acetate, butyl acetate, isobutyl acetate, pentyl acetate, isopentyl acetate, butenyl acetate, propyl formate, butyl formate, isobutyl formate, pentyl formate, isopentyl formate, methyl valerate, methyl pentenoate, methyl crotonate, ethyl crotonate, methyl propionate, ethyl propionate, ethyl 3-ethoxypropionate, methyl lactate, ethyl lactate, propyl lactate, butyl lactate, isobutyl lactate, pentyl lactate, isopentyl lactate, methyl 2-hydroxyisobutyrate, ethyl 2-hydroxyisobutyrate, methyl benzoate, ethyl benzoate, phenyl acetate, benzyl acetate, methyl phenylacetate, ethyl phenylacetate, benzyl formate, phenylethyl formate, methyl 3-phenylpropionate, benzyl propionate, and 2-phenylethyl acetate. These organic solvents may be used alone or in admixture of two or more.

At the end of development, the resist film is rinsed if necessary. As the rinsing liquid, a solvent which is miscible with the developer and does not dissolve the resist film is preferred. Suitable solvents include alcohols of 3 to 10 carbon atoms, ether compounds of 8 to 12 carbon atoms, alkanes, alkenes, and alkynes of 6 to 12 carbon atoms, and aromatic solvents. Specifically, suitable alcohols of 3 to 10 carbon atoms include n-propyl alcohol, isopropyl alcohol, 1-butyl alcohol, 2-butyl alcohol, isobutyl alcohol, tert-butyl alcohol, 1-pentanol, 2-pentanol, 3-pentanol, tert-pentyl alcohol, neopentyl alcohol, 2-methyl-1-butanol, 3-methyl-1-butanol, 3-methyl-3-pentanol, cyclopentanol, 1-hexanol, 2-hexanol, 3-hexanol, 2,3-dimethyl-2-butanol, 3,3-dimethyl-1-butanol, 3,3-dimethyl-2-butanol, 2-ethyl-1-butanol, 2-methyl-1-pentanol, 2-methyl-2-pentanol, 2-methyl-3-pentanol, 3-methyl-1-pentanol, 3-methyl-2-pentanol, 3-methyl-3-pentanol, 4-methyl-1-pentanol, 4-methyl-2-pentanol, 4-methyl-3-pentanol, cyclohexanol, and 1-octanol. Suitable ether compounds of 8 to 12 carbon atoms include di-n-butyl ether, diisobutyl ether, di-sec-butyl ether, di-n-pentyl ether, diisopentyl ether, di-sec-pentyl ether, di-tert-pentyl ether, and di-n-hexyl ether. Suitable alkanes of 6 to 12 carbon atoms include hexane, heptane, octane, nonane, decane, undecane, dodecane, methylcyclopentane, dimethylcyclopentane, cyclohexane, methylcyclohexane, dimethylcyclohexane, cycloheptane, cyclooctane, and cyclononane. Suitable alkenes of 6 to 12 carbon atoms include hexene, heptene, octene, cyclohexene, methylcyclohexene, dimethylcyclohexene, cycloheptene, and cyclooctene. Suitable alkynes of 6 to 12 carbon atoms include hexyne, heptyne, and octyne. Suitable aromatic solvents include toluene, xylene, ethylbenzene, isopropylbenzene, tert-butylbenzene and mesitylene.

Rinsing is effective for minimizing the risks of resist pattern collapse and defect formation. However, rinsing is not essential. If rinsing is omitted, the amount of solvent used may be reduced.

### EXAMPLES

Examples of the invention are given below by way of illustration and not by way of limitation. The abbreviation “pbw” is parts by weight. Analysis is made by IR spectroscopy, NMR spectroscopy, and time-of-flight mass spectrometry (TOF-MS) using analytic instruments as shown below.
IR: NICOLET 6700 by Thermo Fisher Scientific Inc.
¹H-NMR: ECA-500 by JEOL Ltd.
MALDI TOF-MS: S3000 by JEOL Ltd.

### [1] Synthesis of Sulfonium Salts

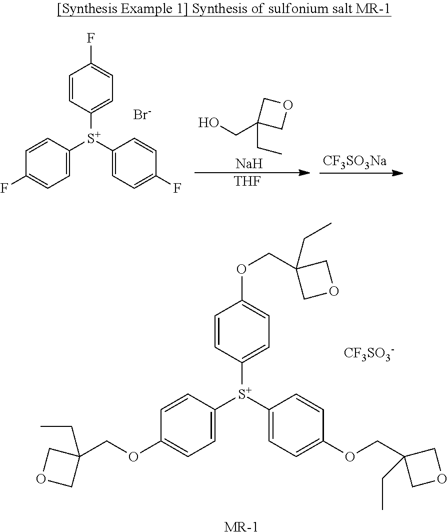

In nitrogen atmosphere, 4.7 g of 3-ethyl-3-oxetane methanol was added dropwise to 1.6 g of sodium hydride in 40 g of tetrahydrofuran. At the end of addition, the solution was aged at room temperature for 2 hours. Under ice cooling, 4.0 g of tris(4-fluorophenyl) sulfonium bromide was added to the solution. The reaction solution was aged at room temperature for 4 hours. Thereafter, 30 g of ultrapure water was added to the reaction solution. The solution was washed with diisopropyl ether, 50 g of dichloromethane and 3.4 g of sodium trifluoromethanesulfonate were added, and stirring was continued for 30 minutes. The reaction solution was allowed to separate into two layers. The organic layer was taken out, washed with ultrapure water, and concentrated under reduced pressure. Further, methyl isobutyl ketone (MIBK) was added to the concentrate, which was again concentrated under reduced pressure. Water was azeotroped off, obtaining 7.7 g of an oily matter. On ¹H-NMR analysis, the oily matter was identified to be sulfonium salt MR-1 containing MIBK. Yield as isolated 66%.

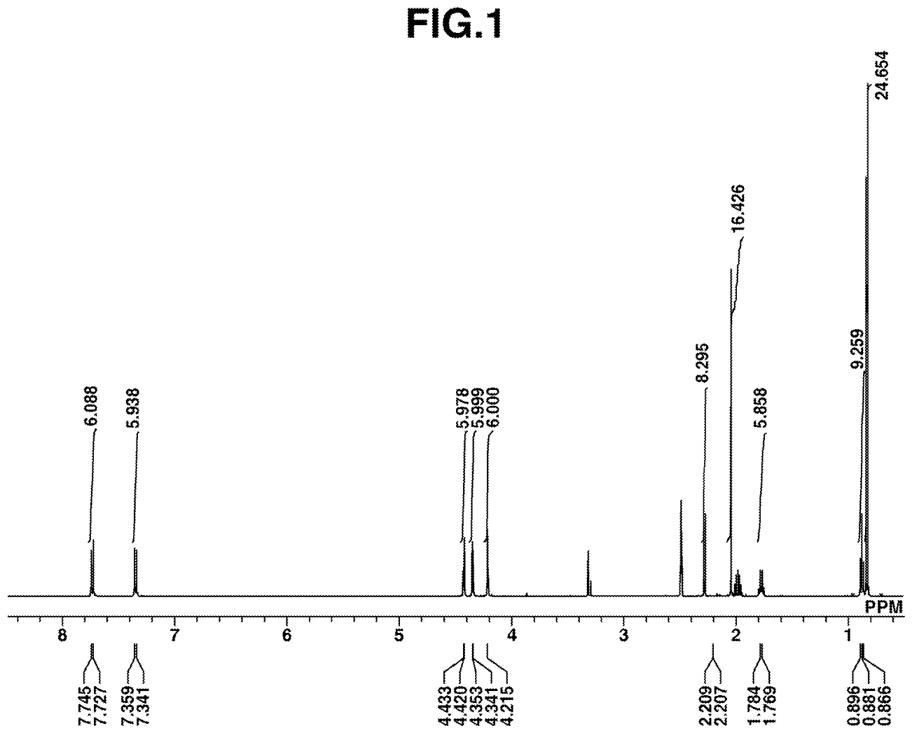

Sulfonium salt MR-1 was analyzed by spectroscopy, with the data shown below. FIG. 1 is the 1H-NMR/DMSO-d6 spectrum of MR-1.

IR (D-ATR): 2958, 2872, 1711, 1588, 1575, 1496, 1461, 1366, 1305, 1262, 1223, 1178, 1152, 1075, 1031, 1016, 982, 832, 638, 528 cm⁻¹

### MALDI-TOFMS

Positive M+605 (corresponding to C₃₆H₄₅O₆S+)
Negative M−148 (corresponding to CF₃SO₃⁻)

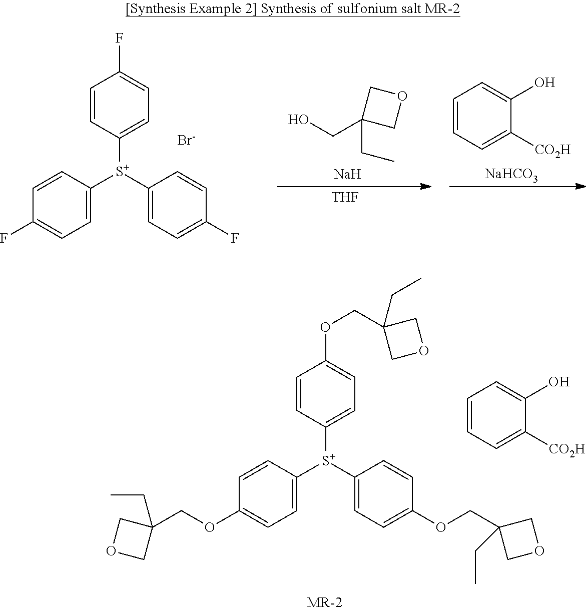

In nitrogen atmosphere, 4.7 g of 3-ethyl-3-oxetane methanol was added dropwise to 1.6 g of sodium hydride in 40 g of tetrahydrofuran. At the end of addition, the solution was aged at room temperature for 2 hours. Under ice cooling, 4.0 g of tris(4-fluorophenyl) sulfonium bromide was added to the solution. The reaction solution was aged at room temperature for 4 hours. Thereafter, 30 g of saturated sodium bicarbonate water was added to the reaction solution. The solution was washed with diisopropyl ether, 50 g of dichloromethane and 1.7 g of salicylic acid were added, and stirring was continued for 30 minutes. The reaction solution was allowed to separate into two layers. The organic layer was taken out, washed with ultrapure water, and concentrated under reduced pressure. Further, propylene glycol monomethyl acetate (PGMEA) was added to the concentrate, which was again concentrated under reduced pressure. Water was azeotroped off, obtaining 9.2 g of an oily matter. On 1H-NMR analysis, the oily matter was identified to be a sulfonium salt MR-2 containing PGMEA. Yield as isolated 72%.

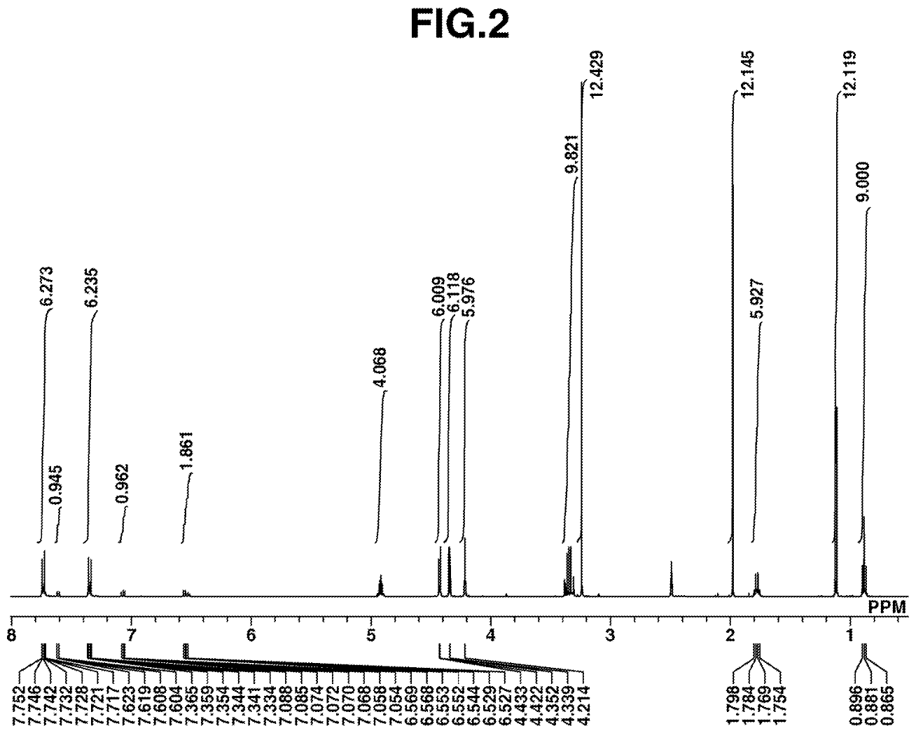

Sulfonium salt MR-2 was analyzed by spectroscopy, with the data shown below. FIG. 2 is the 1H-NMR/DMSO-d6 spectrum of MR-2.

IR (D-ATR): 2965, 2935, 2875, 1734, 1588, 1495, 1458, 1373, 1304, 1258, 1245, 1203, 1178, 1114, 1074, 1018, 978, 830, 529 cm⁻¹

### MALDI-TOFMS

Positive M+605 (corresponding to C₃₆H₄₅O₆S+)
Negative M−138 (corresponding to C₇H₆O₃⁻)

### [Synthesis Examples 3 to 7] Synthesis of Sulfonium Salts MR-3 to MR-7

Sulfonium salts MR-3 to MR-7 shown below were synthesized by the same procedure as Synthesis Example 1.

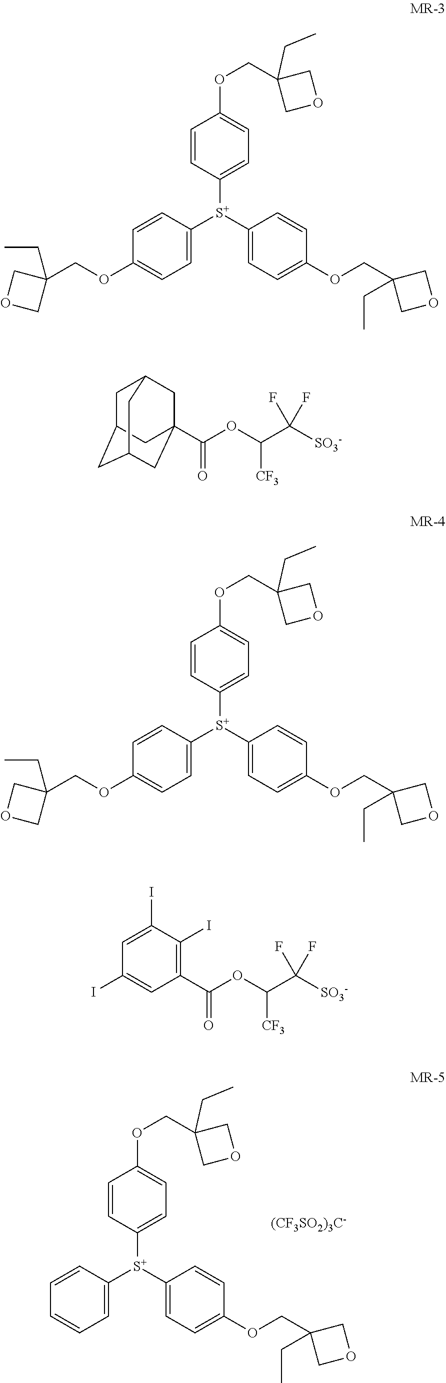

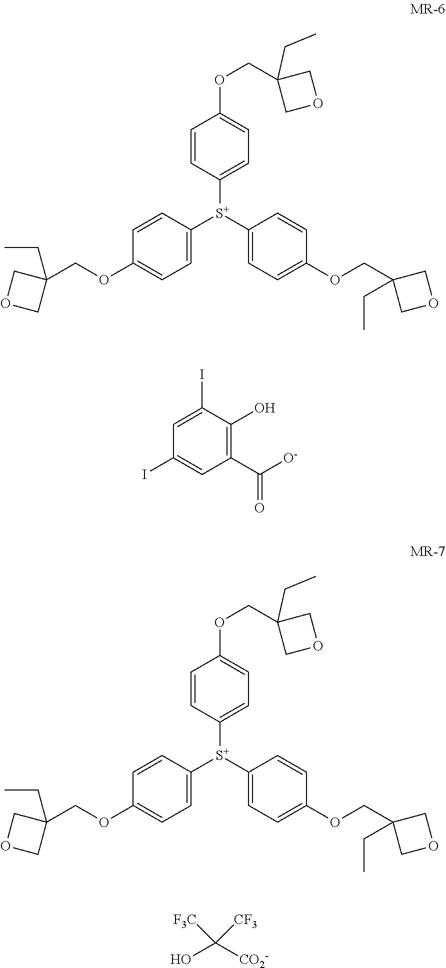

### [2] Synthesis of Base Polymer for Comparative Resist Composition

### [Comparative Synthesis Example 1] Synthesis of Polymer P-1

In nitrogen atmosphere, 27.8 g of p-hydroxystyrene, 72.2 g of 1-methylcyclopentyl methacrylate, and 6.08 g of dimethyl 2,2′-azobisisobutyrate were dissolved in 155 g of PGMEA. In nitrogen atmosphere and with stirring, the solution was added dropwise to 78 g of PGMEA at 80° C. over 6 hours. At the end of addition, the solution was stirred for 2 hours while maintaining the temperature of 80° C. The solution was cooled to room temperature, after which it was added dropwise to 3,000 g of n-hexane for precipitation. The solid precipitate was filtered and dried in vacuum at 50° C. for 20 hours, obtaining Polymer P-1 in white powder form. Amount 85 g and yield 85%.

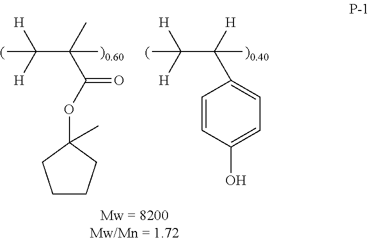

### [Comparative Synthesis Example 2] Synthesis of Polymer P-2

Polymer P-2 was synthesized by the same procedure as in Comparative Synthesis Example 1 aside from changing the type and mixing ratio of monomers.

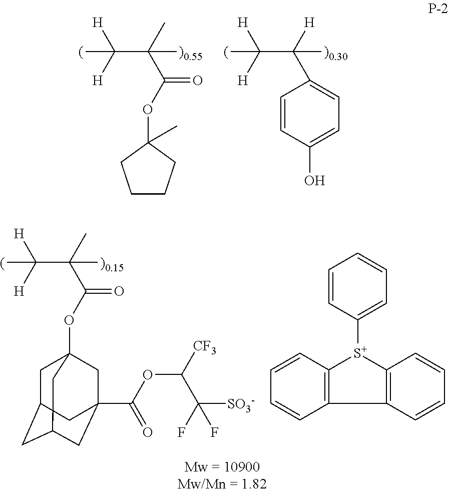

### [3] Preparation of Resist Composition

### Examples 1-1 to 1-8 and Comparative Examples 1-1 to 1-3

Molecular resist compositions (R-01 to R-08) were prepared in solution form by mixing selected components in accordance with the formulation shown in Table 1, and filtering through a Teflon® filter with a pore size of 0.2 μm. Comparative resist compositions (CR-1 to CR-3) were prepared in solution form by mixing selected components in accordance with the formulation shown in Table 1, and filtering through a Teflon® filter with a pore size of 0.2 μm.

TABLE 1

| | | Resist | Component A | Component B | Component C | Solvent 1 | Solvent 2 |
|---|---|---|---|---|---|---|---|
| | | composition | (pbw) | (pbw) | (pbw) | (pbw) | (pbw) |
| Example | 1-1 | R-01 | MR-1 (30) | AQ-1 (6) | — | PGMEA (1,500) | DAA (600) |
| | 1-2 | R-02 | MR-1 (15) | MR-2 (15) | — | PGMEA (1,500) | DAA (600) |
| | 1-3 | R-03 | MR-1 (15) | MR-7 (16) | — | PGMEA (1,500) | DAA (600) |
| | 1-4 | R-04 | MR-1 (15) | MR-7 (10) | — | PGMEA (1,500) | DAA (600) |
| | 1-5 | R-05 | MR-3 (20) | MR-2 (15) | — | PGMEA (1,500) | DAA (600) |
| | 1-6 | R-06 | MR-4 (26) | MR-2 (15) | — | PGMEA (1,500) | DAA (600) |
| | 1-7 | R-07 | MR-5 (18) | MR-2 (15) | — | PGMEA (1,500) | DAA (600) |
| | 1-8 | R-08 | MR-4 (32) | — | — | PGMEA (1,500) | DAA (600) |
| Comparative | 1-1 | CR-01 | P-1 (65) | PAG-1 (31) | PDB-1 (19) | PGMEA (1,500) | DAA (600) |
| Example | 1-2 | CR-02 | P-2 (65) | — | PDB-1 (19) | PGMEA (1,500) | DAA (600) |
| | 1-3 | CR-03 | CMR-1 (54) | PAG-2 (10) | AQ-1 (0.3) | PGMEA(1,500) | DAA (600) |

The photoacid generators (PAG-1, PAG-2), quencher (AQ-1, PDB-1), comparative compound (CMR-1), surfactant (SF-1), and solvents in Table 1 are identified below. It is noted that PAG-1 was synthesized with reference to JP-A 2012-236816 and CMR-1 was synthesized with reference to JP-A 2013-205521.

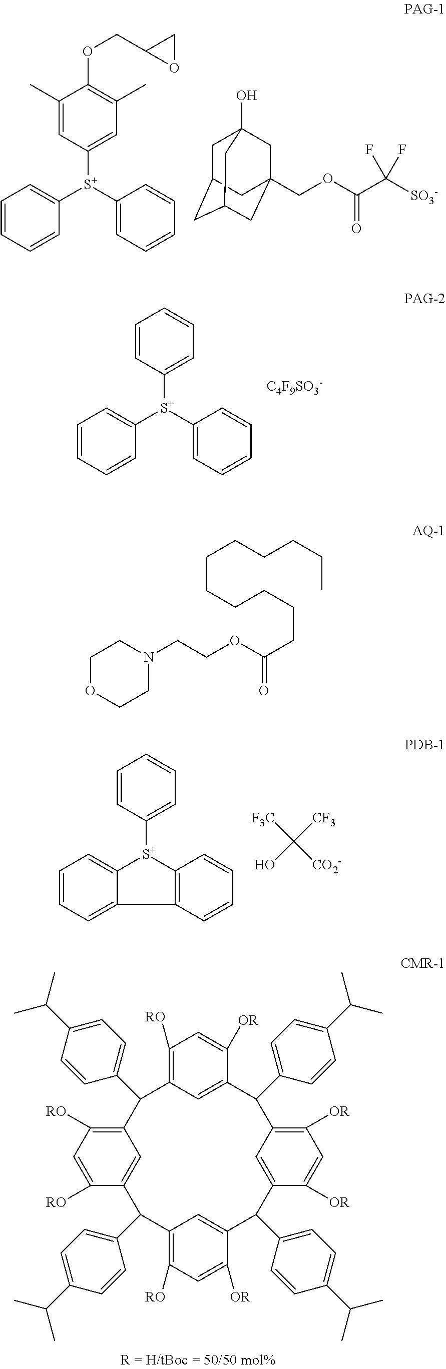

Herein, tBOC stands for tert-butoxycarbonyl.

SF-1: PF636 (Omnova Solutions Inc.)

### Solvent:

PGMEA (propylene glycol monomethyl ether acetate)
DAA (diacetone alcohol)
   [4] EUV lithography test

### Examples 2-1 to 2-8, Comparative Examples 2-1 to 2-3, Examples 3-1 to 3-8 and Comparative Examples 3-1 to 3-3

Each of the resist compositions (R-01 to R-08, CR-01 to CR-03) was spin coated on a silicon substrate having a 20-nm coating of silicon-containing spin-on hard mask (SHB-A940 by Shin-Etsu Chemical Co., Ltd., silicon content 43 wt %) and prebaked on a hotplate at the temperature shown in Table 2 or 3 for 60 seconds to form a resist film of 40 nm thick. Using an EUV scanner NXE3400 (ASML, NA 0.33, σ 0.9, 90° dipole illumination), the resist film was exposed to EUV through a mask bearing a 48-nm 1:1 line-and-space (LS) pattern. The resist film was baked (PEB) on a hotplate at the temperature shown in Table 2 or 3 for 60 seconds and developed in a developer for 30 seconds to form a pattern. In Examples 2-1 to 2-8 and Comparative Examples 2-1 to 2-3, the developer was a 2.38 wt % TMAH aqueous solution. In Examples 3-1 to 3-8 and Comparative Examples 3-1 to 3-3, the developer was butyl acetate. A LS pattern having a space width of 24 nm and a pitch of 48 nm was formed.

The LS pattern was observed under an electron microscope CD-SEM (CG-6300 by Hitachi High-Technologies Corp.). The LS pattern was evaluated for sensitivity, LWR, and maximum resolution by the following methods.

### [Evaluation of Sensitivity]

The optimum dose Eop (mJ/cm²) which provided a LS pattern with a space width of 24 nm and a pitch of 48 nm was determined and reported as sensitivity.

### [Evaluation of LWR]

For the LS pattern formed by exposure in the optimum dose Eop, the space width was measured at longitudinally spaced apart 10 points, from which a 3-fold value (36) of the standard deviation (σ) was determined and reported as LWR. A smaller value of 30 indicates a pattern having a lower roughness and more uniform space width.

### [Evaluation of Maximum Resolution]

An LS pattern was formed while increasing the exposure dose little by little from the optimum dose (Eop). The line width (nm) which could be resolved was determined and reported as maximum resolution. A smaller value indicates a pattern having a better maximum resolution and smaller feature size.

Table 2 shows the evaluation results of the patterns developed in 2.38 wt % TMAH aqueous solution. Table 3 shows the evaluation results of the patterns developed in butyl acetate.

TABLE 2

| | | Resist | Development | PEB | Eop | LWR | Maximum resolution |
|---|---|---|---|---|---|---|---|
| | | composition | tone | (° C.) | (mJ/cm²) | (nm) | (nm) |
| Example | 2-1 | R-01 | negative | 110 | 56 | 3.7 | 16 |
| | 2-2 | R-02 | negative | 110 | 52 | 3.4 | 18 |
| | 2-3 | R-03 | negative | 110 | 48 | 3.5 | 18 |
| | 2-4 | R-04 | negative | 110 | 54 | 3.6 | 18 |
| | 2-5 | R-05 | negative | 110 | 52 | 3.4 | 18 |
| | 2-6 | R-06 | negative | 110 | 50 | 3.3 | 16 |
| | 2-7 | R-07 | negative | 110 | 56 | 3.4 | 18 |
| | 2-8 | R-08 | negative | 100 | 45 | 3.8 | 18 |
| Comparative | 2-1 | CR-01 | positive | 110 | 82 | 4.8 | 22 |
| Example | 2-2 | CR-02 | positive | 110 | 64 | 4.2 | 20 |
| | 2-3 | CR-03 | positive | 110 | 60 | 5.0 | 24 |

TABLE 3

| | | Resist | Development | PEB | Eop | LWR | Maximum resolution |
|---|---|---|---|---|---|---|---|
| | | composition | tone | (° C.) | (mJ/cm²) | (nm) | (nm) |
| Example | 3-1 | R-01 | negative | 110 | 60 | 3.6 | 18 |
| | 3-2 | R-02 | negative | 110 | 53 | 3.2 | 16 |
| | 3-3 | R-03 | negative | 110 | 52 | 3.3 | 18 |
| | 3-4 | R-04 | negative | 110 | 56 | 3.5 | 16 |
| | 3-5 | R-05 | negative | 110 | 56 | 3.2 | 18 |
| | 3-6 | R-06 | negative | 110 | 52 | 3.3 | 16 |
| | 3-7 | R-07 | negative | 110 | 54 | 3.1 | 18 |
| | 3-8 | R-08 | negative | 100 | 48 | 3.6 | 16 |
| Comparative | 3-1 | CR-01 | negative | 110 | 62 | 4.8 | 26 |
| Example | 3-2 | CR-02 | negative | 110 | 60 | 4.5 | 24 |
| | 3-3 | CR-03 | negative | 110 | 94 | 5.7 | 40 |

It is evident from Tables 2 and 3 that the molecular resist compositions within the scope of the invention are improved in sensitivity, LWR and maximum resolution over conventional polymeric positive resist compositions and molecular resist compositions when patterns are formed by the EUV lithography.

Japanese Patent Application No. 2023-065363 is incorporated herein by reference. Although some preferred embodiments have been described, many modifications and variations may be made thereto in light of the above teachings. It is therefore to be understood that the invention may be practiced otherwise than as specifically described without departing from the scope of the appended claims.

1. A negative-tone molecular resist composition comprising an onium salt containing a cation having a cyclic ether site and an organic solvent, the composition being free of a base polymer.

2. The molecular resist composition of claim 1 wherein the onium salt is a sulfonium salt having the formula (1): 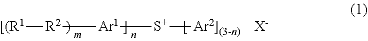
wherein m is an integer of 1 to 3, n is an integer of 1 to 3,
R¹ is a substituent group having a cyclic ether site, a plurality of R¹ may be the same or different when at least one of m and n is 2 or 3,
R² is a single bond, ether bond, ester bond, —N(H)—, thioether bond, sulfonate ester bond, sulfonamide bond, carbonate bond or carbamate bond,
Ar¹ is a C₆-C₂₀ (m+1)-valent aromatic hydrocarbon group in which some or all of the hydrogen atoms on the aromatic ring may be substituted by halogen or a C₁-C₂₀ hydrocarbyl moiety which may contain a heteroatom, a plurality of Ar¹ may be the same or different when n is 2 or 3,
Ar² is a C₆-C₂₀ aryl group in which some or all of the hydrogen atoms on the aromatic ring may be substituted by halogen or a C₁-C₂₀ hydrocarbyl moiety which may contain a heteroatom, two Ar² may be the same or different when n is 1,
two Ar¹, two Ar², or Ar¹ and Ar² may bond together to form a ring with the sulfur atom to which they are attached, and
X⁻ is a counter anion.

3. The molecular resist composition of claim 1 wherein the cyclic ether site is an oxirane or oxetane ring.

4. The molecular resist composition of claim 2 wherein X⁻ is a halide ion, nitrate ion, hydrogensulfate ion, hydrogencarbonate ion, borate ion, hexafluorophosphate ion, hexafluoroantimonate ion or an anion having any one of the formulae (X-1) to (X-7): 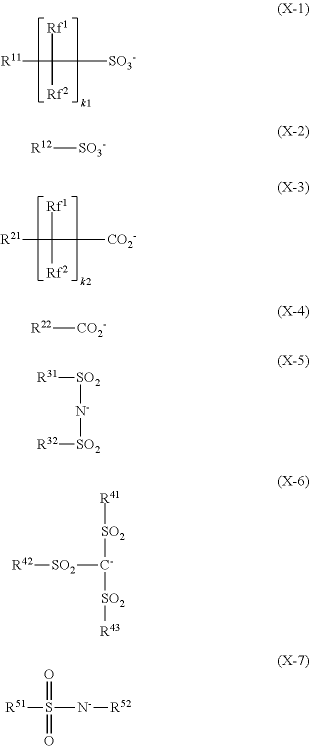
wherein k1 and k2 are each independently an integer of 1 to 4,
Rf¹ and Rf² are each independently hydrogen, fluorine or a C₁-C₆ fluorinated alkyl group, excluding that all Rf¹ and Rf² are hydrogen at the same time,
R¹¹ is hydrogen, halogen, hydroxy, or a C₁-C₄₀ hydrocarbyl group which may contain a heteroatom,
R¹² is hydrogen, halogen, hydroxy, or a C₁-C₄₀ hydrocarbyl group which may contain a heteroatom, exclusive of a hydrocarbyl group in which hydrogen on β- or β-carbon relative to the sulfo group is substituted by fluorine or fluoroalkyl,
R²¹ is hydrogen, halogen, hydroxy, or a C₁-C₄₀ hydrocarbyl group which may contain a heteroatom,
R²² is hydrogen, halogen, hydroxy, or a C₁-C₄₀ hydrocarbyl group which may contain a heteroatom, exclusive of a hydrocarbyl group in which hydrogen on β- or β-carbon relative to the carboxy group is substituted by fluorine or fluoroalkyl,
R³¹ and R³² are each independently a C₁-C₄₀ hydrocarbyl group which may contain a heteroatom,
R⁴¹ to R⁴³ are each independently a C₁-C₄₀ hydrocarbyl group which may contain a heteroatom,
R⁵¹ is fluorine or a C₁-C₁₀ fluorinated hydrocarbyl group which may contain hydroxy, ether bond or ester bond, R⁵² is hydrogen or a C₁-C₂₀ hydrocarbyl group which may contain hydroxy, ether bond or ester bond, R⁵¹ and R⁵² may bond together to form a ring with the atoms to which they are attached.

5. The molecular resist composition of claim 1, further comprising an amine compound.

6. The molecular resist composition of claim 1, comprising at least two onium salts containing a cation having a cyclic ether site.

7. The molecular resist composition of claim 1, further comprising an onium salt other than the onium salt containing a cation having a cyclic ether site.

8. The molecular resist composition of claim 1, further comprising a surfactant.

9. A pattern forming process comprising the steps of applying the negative-tone molecular resist composition of claim 1 onto a substrate to form a resist film thereon, exposing the resist film to high-energy radiation, and developing the exposed resist film in a developer.

10. The process of claim 9 wherein the developing step uses an alkaline aqueous solution as the developer to form a negative tone pattern wherein the resist film in the unexposed region is dissolved away and the resist film in the exposed region is not dissolved.

11. The process of claim 9 wherein the developing step uses an organic solvent as the developer to form a negative tone pattern wherein the resist film in the unexposed region is dissolved away and the resist film in the exposed region is not dissolved.

12. The process of claim 11 wherein the organic solvent is at least one solvent selected from among 2-octanone, 2-nonanone, 2-heptanone, 3-heptanone, 4-heptanone, 2-hexanone, 3-hexanone, diisobutyl ketone, methylcyclohexanone, acetophenone, methylacetophenone, propyl acetate, butyl acetate, isobutyl acetate, pentyl acetate, butenyl acetate, isopentyl acetate, propyl formate, butyl formate, isobutyl formate, pentyl formate, isopentyl formate, methyl valerate, methyl pentenoate, methyl crotonate, ethyl crotonate, methyl propionate, ethyl propionate, ethyl 3-ethoxypropionate, methyl lactate, ethyl lactate, propyl lactate, butyl lactate, isobutyl lactate, pentyl lactate, isopentyl lactate, methyl 2-hydroxyisobutyrate, ethyl 2-hydroxyisobutyrate, methyl benzoate, ethyl benzoate, phenyl acetate, benzyl acetate, methyl phenylacetate, benzyl formate, phenylethyl formate, methyl 3-phenylpropionate, benzyl propionate, and 2-phenylethyl acetate.

13. The process of claim 9 wherein the high-energy radiation is EB or EUV.
